(19) United States
(12) Patent Application Publication
(10) Pub. No.: US 2023/0071117 A1
(43) Pub. Date: Mar. 9, 2023

(54) MULTIPLEXED RANKS (MR) WITH PSEUDO BURST LENGTH 32 (BL32)

(71) Applicant: Intel Corporation, Santa Clara, CA (US)

(72) Inventors: Hussein ALAMEER, Portland, OR (US); Bill NALE, Livermore, CA (US); George VERGIS, Portland, OR (US); Rajat AGARWAL, Portland, OR (US)

(21) Appl. No.: 17/987,687

(22) Filed: Nov. 15, 2022

(51) Int. Cl. G06F 3/06

(52) U.S. Cl. CPC G06F 3/0625; G06F 3/0673; G06F 3/0655

(57) ABSTRACT

A memory module has a registering clock driver (RCD) that issues two column address strobe (CAS) commands with a single memory access command to exchange a double amount of data per dynamic random access memory (DRAM) device per memory access command. With double the amount of data per DRAM device, the memory module can provide double the pseudo channels as compared to a memory module where a single CAS command is issued per access command. The RCD can time division multiplex separate first commands for a first group of the DRAM devices from second commands for a second group of the DRAM devices on the command/address (CA) bus.

### FIELD

Descriptions are generally related to memory subsystems, and more particular descriptions are related to memory modules.

### BACKGROUND

System memory in computer systems is often provided with a DIMM (dual inline memory module) that includes multiple DRAM (dynamic random access memory) devices. To reduce the loading on the system memory bus by the DRAM devices, LRDIMMs (load reduced DIMM) can be used, which includes a registering clock driver (RCD) and multiple data buffers. The RCD receives the commands and passes commands to the DRAM devices and the data buffers to manage the data transmission between the DRAM devices and the host.

There are LRDIMM implementations that divide the devices on the DIMM into two pseudo channels that can transfer data simultaneously and improve data throughput. The data buffers for the pseudo channels send data from both pseudo channels onto the host data bus. A DIMM with multiple pseudo channels can be referred to as a multiplexed ranks (MR) DIMM (previously referred to as multiplexed combined ranks DIMM (“MCR DIMM”)).

MRDIMMs currently only support double data rate version 5 (DDR5) DRAM devices, which can have very high power consumption in some modes in an MRDIMM. Multiplexed ranks is designed to double the bandwidth of the DIMM. However, scaling bandwidth linearly increases power consumption. Additionally, separating the DRAM devices into pseudo channels can limit bandwidth scaling due to limits on the number of banks available in parallel.

### BRIEF DESCRIPTION OF THE DRAWINGS

The following description includes discussion of figures having illustrations given by way of example of an implementation. The drawings should be understood by way of example, and not by way of limitation. As used herein, references to one or more examples are to be understood as describing a particular feature, structure, or characteristic included in at least one implementation of the invention. Phrases such as “in one example” or “in an alternative example” appearing herein provide examples of implementations of the invention, and do not necessarily all refer to the same implementation. However, they are also not necessarily mutually exclusive.

FIG. 1 is a block diagram of an example of a system with a memory module having pseudo channels.

FIG. 2 is a block diagram of an example of an LRDIMM with four pseudo channels per channel with ×8 devices.

FIG. 3 is a block diagram of an example of an LRDIMM with four pseudo channels per channel with ×8 devices and additional chip selects.

FIG. 4 is a block diagram of an example of data timing for a system with pseudo channels.

FIG. 5 is a block diagram of an example of signaling for a memory module with pseudo channels.

FIG. 6 is a block diagram of an example of an LRDIMM with four pseudo channels per channel with ×16 devices and additional chip selects.

FIG. 7 is a block diagram of an example of an LRDIMM with four pseudo channels per channel with ×8 devices and same-PCH buffer multiplexing.

FIG. 8 is a block diagram of an example of an LRDIMM with four pseudo channels per channel with ×16 devices on two sides and same-PCH buffer multiplexing.

FIG. 9 is a block diagram of an example of an LRDIMM with four pseudo channels per channel with ×16 devices on one side and same-PCH buffer multiplexing.

FIG. 10 is a block diagram of an example of a registered clock driver.

FIG. 11 is a block diagram of an example of a data buffer.

FIG. 12 is a block diagram of an example of a memory subsystem in which pseudo channels can be implemented.

FIG. 13 is a block diagram of an example of a computing system in which pseudo channels can be implemented.

FIG. 14 is a block diagram of an example of a multi-node network in which pseudo channels can be implemented.

Descriptions of certain details and implementations follow, including non-limiting descriptions of the figures, which may depict some or all examples, and well as other potential implementations.

### DETAILED DESCRIPTION

As described herein, a memory module has a registering clock driver (RCD) that issues two column address strobe (CAS) commands with a single memory access command to exchange a double amount of data per dynamic random access memory (DRAM) device per memory access command. With double the amount of data per DRAM device, the memory module can provide double the pseudo channels as compared to a memory module where a single CAS command is issued per access command. “Pseudo channel” can be abbreviated as “PCH”, and can alternatively be referred to as pseudo-channel or pseudochannel. The RCD can time division multiplex separate first commands for a first group of the DRAM devices from second commands for a second group of the DRAM devices on the command/address (CA) bus.

The ability of the RCD to multiplex commands to different groups and provide multiple CAS commands per memory access command can enable a multiplexed ranks (MR) dual inline memory module (DIMM) that can better manage power with increased bandwidth scaling. Specific implementations provide options to manage the tradeoff between bandwidth and power consumption.

The MRDIMM can have one or more new modes of operation based on double data rate version 5 (DDR5) DRAM device configurations behind the data buffer, which can be referred to as the MR buffer. An MRDIMM can be implemented with twice as many pseudo channels, using lower power per bit relative to a DDR5 MRDIMM that applies only a single CAS per memory access command. Certain implementations contemplate the use of ×8 DRAMs, referring to DRAM devices that have 8 pins to couple to a data bus. The application of the MRDIMM can be extended to ×16 devices (DRAM devices that have 16 pins to couple to a data bus).

In one example, the MRDIMM can implement a burst length 32 (BL32), referring to exchanging data from each of the interface pins for 32 consecutive unit intervals (UIs) in response to a single memory access command. More specifically, each DRAM device would transmit a bit of data per data interface (DQ) pin per UI in response to a read command, and each DRAM device would receive a bit of data per DQ pin per UI in response to a write command. Without the second CAS command, a single data access command would have a burst length 16 (BL16). In certain implementations, the system can include additional chip select signal lines on the MRDIMM to allow the RCD to address the extra PCH.

By changing the DIMM to have more pseudo channels (PCH), the memory can provide power savings for the system. The MRDIMM can provide higher power efficiency, which translates to higher performance in power constrained systems. As described herein, the MRDIMM can have new configurations that allow logically adding more pseudo-channels. The configurations can provide a single 64B cacheline plus error correction ECC from 2 ×8 device instead of 4 ×8 devices+1 ×8 ECC device. The MRDIMM can be extended to use ×16 devices without sacrificing capacity or performance, even though ×16 devices have half the bank count relative to ×8 devices, which normally leads to higher timing penalties.

In one example, an MRDIMM with BL32 lacks dedicated ECC devices, whereas an MRDIMM with BL16 has dedicated ECC devices. Simulations of the MRDIMM with BL32 shows power savings over an MRDIMM with BL16, due to removing the dedicated ECC devices, removing data buffers from the DIMM, and increasing the device-level page hit rate. The doubling of the burst length can relieve bank pressure, with simulation showing an increase of performance as a result. Additionally, simulations show that increasing the number of PCHs and extending the burst length can improve provide comparable performance for a ×16 configuration as compared to a ×8 configuration despite the reduced bank count of the ×16 devices.

For purposes of description herein, reference is made to DRAM devices and DIMMs. More specific examples are directed to load reduced DIMMs (LRDIMMs). Reference to an LRDIMM or a memory module will be understood as referring to a module or unit that includes multiple DRAM devices accessed through one or more data buffers. The DRAM devices on the module can be managed as multiple pseudo channels, where the BCOM commands to the data buffer enable the data buffer to manage the access to the DRAM devices with desired timing and configurations. In addition to DIMMs, other types of memory module that allow for the parallel connection of memory devices can be used, such as a multichip package (MCP) with multiple memory devices in a stack.

In one specific example, the use of DRAM devices in an LRDIMM as multiple pseudo channels can be governed by a standard. An application of an LRDIMM with DDR5 (double data rate version 5, JESD79-5, originally published by JEDEC (Joint Electron Device Engineering Council) in July 2020)) DRAMs can be defined for an MRDIMM configuration. In the MR configuration, the DRAMs can be configured in ranks (e.g., devices on the front and devices on the back of the DIMM board), with multi-channel LRDIMMs (e.g., Channel 0 and Channel 1 or Channel A and Channel B), as well as being divided in pseudo channels (e.g., pseudo channel 0 (PCH0), pseudo channel 1 (PCH1), and so forth.

The host memory controller is aware of the configuration of memory as channels and ranks. The host memory controller is aware of the configuration of the memory as pseudo channels, and sends separate commands to the RCD for each pseudo channel. The commands are time multiplexed on the command and address (CA) bus from the host to the RCD. In one example, the command rate on the CA bus from the host to the RCD can be double the rate of the RCD to the DRAMs to enable the host to send a command to each pseudo channel on every DRAM clock. The pseudo channels are described in more detail below.

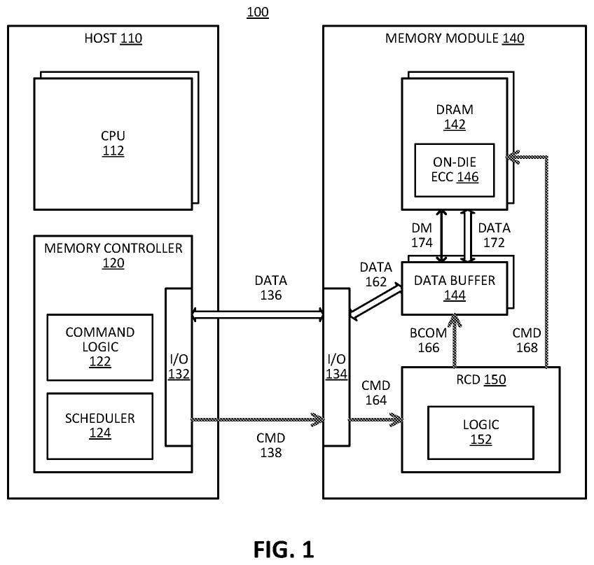

FIG. 1 is a block diagram of an example of a system with a memory module having pseudo channels. System 100 illustrates memory coupled to a host. Host 110 represents a host computing system. Host 110 includes host hardware such as central processing unit (CPU) 112 and memory controller 120. The host hardware also includes hardware interconnects and driver/receiver hardware to provide the interconnection between host 110 and memory module 140. Memory module 140 represents a DIMM or LRDIMM or other multidevice package with memory devices coupled to host 110. Memory module 140 includes data buffers 144 to buffer data for data access to DRAMs 142. Memory controller 120 controls access from the host side to DRAMs 142 of memory module 140. RCD 150 can control access to DRAMs 142 on memory module 140.

The host hardware supports the execution of host software on host 110. The host software can include a host operating system (OS). The host OS represents a software platform under which other software will execute. During execution, software programs, including the host OS, generate requests to access memory. The requests can be directly from host OS software, from other software programs, from requests through application programming interfaces (APIs), or other mechanisms. In response to a host memory access request, memory controller 120 can generate a memory access request for memory module 140.

In one example, memory controller 120 includes command logic 122, which represents logic in memory controller 120 to generate commands to send to the memory devices of memory module 140. The commands can include Read commands for Read transactions and Write commands for Write transactions. Memory controller 120 includes scheduler 124 to schedule how commands will be sent to the memory devices of memory module 140, including controlling the timing of the commands.

Memory controller 120 includes I/O (input/output) 132, which represents interface hardware of host 110 to interconnect host 110 with memory. I/O 134 represents interface hardware on memory module 140 to interconnect with host 110. I/O 132 and I/O 134 can have one or more system buses to interconnect them. System 100 represents data 136 and command (CMD) 138 between I/O 132 and I/O 134. Data 136 represents a data bus, which is typically a bidirectional point to point bus, where the collection of the signal lines to the individual data buffer 144 is collectively referred to as the data bus. Command 138 represents a command bus or command and address (CA) bus, which is typically a unidirectional multidrop bus from the host to the memory.

Memory module 140 includes multiple DRAMs 142, which represent memory devices. Memory module 140 includes data buffers 144, which buffer data 136 between DRAMs 142 and host 110. Data 162 represents the data bus signal lines on memory module 140 from I/O 134 to data buffers 144 and data 172 represents the data bus signal lines from data buffers 144 to DRAMs 142. Command (CMD) 164 represents the signal lines on memory module 140 from I/O 134 to RCD 150. Command (CMD) 168 represents signal lines on memory module 140 from RCD 150 to DRAMs 142 to provide command and device selection (e.g., chip select (CS)) signals. BCOM (buffer communication) 166 represents signal lines from RCD 150 to data buffers 144 to control the operation of the data buffers for memory access commands involving the exchange of data (i.e., read and write commands).

RCD 150 receives commands from host 110 and generates commands on memory module 140 to memory devices to which the host commands are directed. Logic 152 can represent control logic within RCD 150 to control the retiming of command signals. Logic 152 can represent control logic within RCD 150 to control the operation of data buffers 144. More specifically, logic 152 can generate BCOM commands to control the operation and the timing of data buffers 144. In one example, logic 152 includes firmware or software logic. In one example, logic 152 includes hardware logic. In one example, logic 152 includes a combination of hardware and software/firmware logic.

In one example, RCD 150 provides two column address strobe (CAS) instructions for every one read instruction or write instruction to DRAMs 142. Providing multiple CAS commands/instructions for a single access instruction can extend the burst length for the exchange of data associated with the instruction. In one example, memory controller 120 provides the multiple CAS commands for a single access command to RCD 150, which can then send the multiple CAS commands to DRAMs 142. In one example, memory controller 120 provides a single CAS command with a single access command to RCD 150, and RCD 150 then generates an additional CAS command in response to the single access command.

Memory controller 120 is aware of the hardware configuration of memory module 140 (e.g., number of DRAMs, type of DRAM interface, number of internal chip select (CS) lines on memory module 140, data buffer sharing) and is aware of the logical configuration (e.g., organization into pseudo channels, pin sharing). Memory controller 120 is aware of RCD 150 providing additional CAS commands to DRAMs 142, to enable the host to schedule use of the DQ bus for the proper data transfer of data associated with an access command. If RCD 150 is responsible for sending the additional CAS commands, in one example, it will need to keep a counter to manage sending the second CAS command.

In one example, CMD 168 includes more CS signals than CMD 164. The additional CS signals can enable separately addressing DRAMs 142 for additional pseudo channels. In one example, memory module 140 does not include dedicated ECC DRAMs. Thus, DRAMs 142 can all store user data instead of having selected DRAMs 142 dedicated to storing ECC data for reliability, accessibility, and serviceability (RAS) purposes. RAS refers generally to features that enable the system to handle errors to continue to operate.

The use of ECC DRAMs on a DIMM provides the ability to recover from higher bit errors. Removing the ECC DRAMs can reduce the information available to recover from errors. In one example, DRAMs 142 have on die ECC 146, which represents logic on the DRAM die for internally providing ECC. The internal ECC operations of on die ECC 146 is generally not visible to host 110, but allows the DRAM to perform ECC error correction on data prior to sending the data to the host.

In one example, DRAMs 142 provide the storage for the internal ECC bits associated with on die ECC 146 to exchange ECC information with the host that would otherwise be provided to a dedicated ECC DRAM. Thus, system 100 can at least partially make up for the RAS capability lost due to removing the dedicated ECC dies. In one example, system 100 repurposes the data mask (DM) signal line on the side of the connection between data buffers 144 and DRAMs 142. DM 174 represents the data mask signal lines, which can be, for example, one signal line per byte of data (8 signal lines). Data 172 represents the signal lines for the data bus, where there is a DM signal line for a number of data signal lines. In one example, DRAMs 142 expose the internal ECC bits by sending the bits on DM 174 in parallel with sending the user data on data 172 in response to a read command. In one example, DRAMs 142 disable their internal ECC generation to exchange ECC information with the host.

It will be understood that removing the dedicated ECC devices from memory module 140 represents a tradeoff between reduced RAS capability and power savings. System 100 can accommodate certain server segments that require low power, low capacity, with high bandwidth memory, and which can tolerate reduced RAS capability. Such server segments can include certain artificial intelligence (AI) workloads.

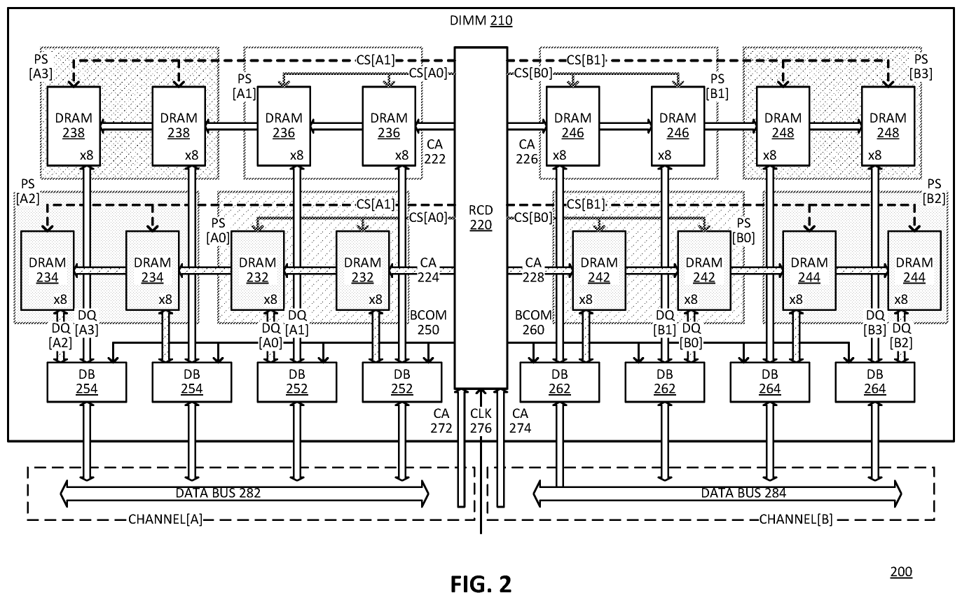

FIG. 2 is a block diagram of an example of an LRDIMM with four pseudo channels per channel with ×8 devices. System 200 represents a system in accordance with an example of system 100. System 200 specifically illustrates dual inline memory module (DIMM) 210, which can be considered an LRDIMM because it includes data buffers. In one example, the operation of the DIMM can be applied to a stacked device or stacked module.

System 200 illustrates one example of DIMM 210 with registered clock driver (RCD) 220, memory devices, and data buffers. RCD 220 represents a controller for DIMM 210. In one example, RCD 220 receives information from a host or a memory controller and buffers the command signals to the memory devices over a CA bus to the memory devices.

The memory devices are represented as DRAM devices, with different ranks as indicated by the different select lines (CS[0], [1], . . . ) and different pseudo channels (PS[0], [1], . . . ). More specifically, DIMM 210 includes two sub channels, Channel A and Channel B (alternatively, Channel 0 and Channel 1). In one example, DIMM 210 includes 4 pseudo channels with front-side devices and without devices on the back. It will be understood that front devices refer to the devices on the same side of the DIMM printed circuit board (PCB) as RCD 220, while the back devices refer to the devices on the opposite side of the DIMM PCB on which the RCD is mounted.

In one example, DIMM 210 includes 4 pseudo channels per channel. As illustrated, Channel A includes PS[A0] including DRAMs 232 connected to CA 224, with chip selects CS[A0]. DRAMs 232 connect to data bus 282 through DBs 252. Channel A includes PS[A1] including DRAMs 236 connected to CA 222, with chip selects CS[A0]. DRAMs 236 connect to data bus 282 through DBs 252, where DBs 252 share DQ[A0] of PS[A0] and DQ[A1] of PS[A1].

Channel A includes PS[A2] including DRAMs 234 connected to CA 224, sharing the CA bus with DRAMs 232 of PS[A0], with chip selects CS[A1]. The sharing by PS[A0] and PS[A1] can refer to time division multiplexing of the signals on the shared lines between the different pseudo channels. DRAMs 234 connect to data bus 282 through DBs 254. Channel A includes PS[A3] including DRAMs 238 connected to CA 222, with chip selects CS[A1]. DRAMs 238 connect to data bus 282 through DBs 254, where DBs 254 share DQ[A2] of PS[A2] and DQ[A3] of PS[A3]

Channel B includes PS[B0] including DRAMs 242 connected to CA 228, with chip selects CS[B0]. DRAMs 242 connect to data bus 284 through DBs 262. Channel B includes PS[B1] including DRAMs 246 connected to CA 226, with chip selects CS[B0]. DRAMs 246 connect to data bus 284 through DBs 262, where DBs 262 share DQ[B0] of PS[B0] and DQ[B1] of PS[B1]. Channel B includes PS[B2] including DRAMs 244 connected to CA 228, sharing the CA bus with DRAMs 242 of PS[B0], with chip selects CS[B1]. The sharing by PS[B0] and PS[B1] can refer to time division multiplexing of the signals on the shared lines between the different pseudo channels. DRAMs 244 connect to data bus 284 through DBs 264. Channel B includes PS[B3] including DRAMs 248 connected to CA 226, with chip selects CS[B1]. DRAMs 248 connect to data bus 284 through DBs 264, where DBs 264 share DQ[B2] of PS[B2] and DQ[B3] of PS[B3].

DIMM 210 includes BCOM bus 250 for DBs 252 and DBs 254 and BCOM bus 260 for DBs 262 and DBs 264. In one example, the BCOM buses are 2 wire buses. In one example, RCD 220 sends Read and Write commands as the primary commands to the data buffers over the BCOM buses. RCD 220 can send the BCOM commands with specific timing to ensure the data buffers know exactly when to transfer data for the different pseudo channels.

RCD 220 can receive multiple signals from the host, including clock (CLK) 276, which represents a clock or timing signal for the commands from the host to RCD 220. The data buses can have their own clock signals (e.g., DQS or data strobe), which are not specifically shown. RCD 220 can receive CA 272, the CA bus from the host for Channel A, and CA 274, the CA bus from the host for Channel B.

In one example, the host command bus (e.g., CA 272, CA 274) operates at twice the data rate of the command buses to the DRAMs (e.g., CA 222, CA 224, CA 226, and CA 228) to accommodate multiple pseudo channels. Thus, for example, the transfer speed of CA bus 272 can be twice the transfer speed of CA 222 and CA 224. Similarly, the transfer speed of CA bus 274 can be twice the transfer speed of CA 226 and CA 228, where the transfer speed of CA bus 272 and CA bus 274 can be equal to each other.

It will be observed that system 200 has two CA buses internally per channel, with CA 272 being the host-side CA bus for Channel A, which RCD uses to control CA 222 and CA 224. Similarly, CA 274 is the host-side CA bus for Channel B, with the RCD having DRAM-side (or RCD-side) CA 226 and CA 228. Splitting the CA bus enables the RCD and data buffers to manage more pseudo channels per sub-channel.

System 200 can represent a new mode of operation, with 4 PCHs per 32-bit sub-channel. In one example, system 200 maintains 2:1 muxing, as does an implementation with 2 PCHs per 32-bit sub-channel. Thus, system 200 can maintain combability between different PCH modes of operation. Where an implementation of 2 PCHs in system 200 could have 4 devices per PCH forming a rank, in system 200, each PCH has 2 devices forming a rank. To construct a 64B cacheline from two ×8 DRAMs, it will be understood that each device needs to send 32 bytes (256 bits), because 64B=64*8, which can be either 4 ×8 devices exchanging data over BL16 or 2 ×8 devices over BL32.

While not specifically shown, the data bus connections through the DBs can include a DM pin per byte of data (DQ) pins. The DM pin can allow the DRAMs to provide ECC information in response to a read command. The ECC information can be exchanged through the internal on-die ECC circuitry.

For an implementation of DDR5, which only natively supports BL16 in ×8 devices, system 200 can apply a pseudo-BL32 through the use of 2 CAS commands per read/write command. It will be understood that a second CAS command would still need to observe DRAM timing limitations such as tCCD_L. Thus, the memory controller can schedule operations to interleave multiple cachelines/bank groups to allow the timing to be observed with two CAS commands. Such a mode of operation can be described as a 1N mode of operation, which has increased latency due to the timing between the two CAS commands. The 1N mode refers to an implementation with memory devices on one side of the DIMM.

An implementation with memory device on both sides of the DIMM, referring to front devices and back devices, can be referred to as a 2N mode. Doubling to a pseudo-BL32 mode with four pseudo channels can have latency constraints. The 1N mode needs to meet tight timing and signal integrity requirements. The 2N mode allows access to more devices, which can address latency issues present in the 1N mode, relaxing the timing and making it easier to meet timing and signal integrity requirements. However, the 2N mode requires additional chip select lines to address potential bandwidth limitations, whereas the 1N mode does not require the additional hardware and does not cut the command bandwidth in half as the 2N mode does. Thus, an MRDIMM can have 1N and 2N options as a tradeoff between bandwidth and capacity with different implementations for an increase in hardware, multiplexing, and more logic within the RCD.

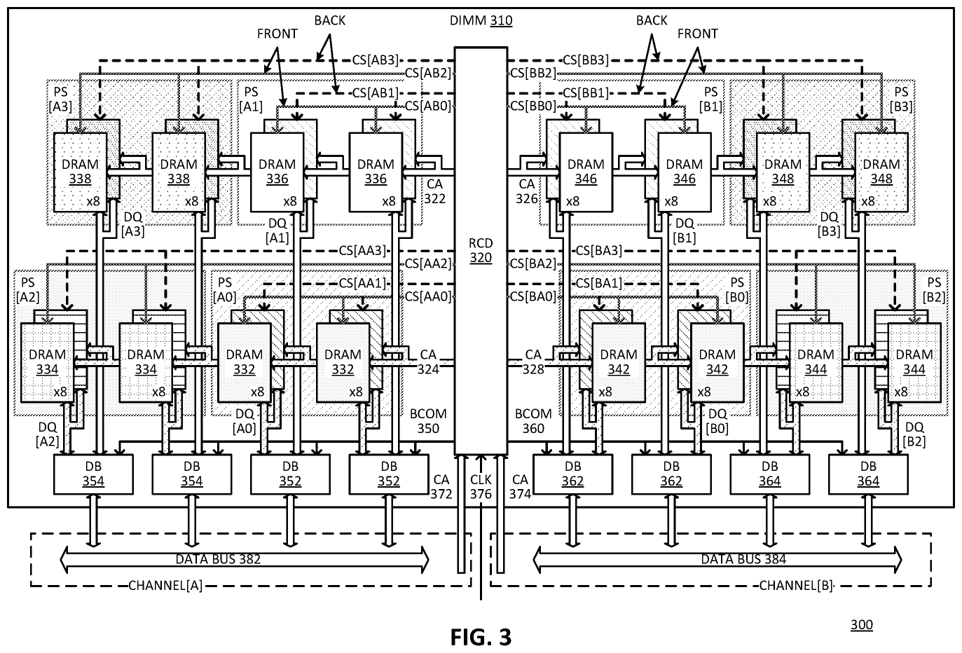

FIG. 3 is a block diagram of an example of an LRDIMM with four pseudo channels per channel with ×8 devices and additional chip selects. System 300 represents a system in accordance with an example of system 100. System 200 of FIG. 2 represents an example of a 1N mode. System 300 represents an example of a 2N mode.

System 300 illustrates DIMM 310 with RCD 320 to manage commands from the host to the DRAM devices, and to control the operation of the data buffers for the exchange of data. System 300 illustrates DIMM 310 having 4 pseudo channels with front-side devices and backside devices.

Channel A includes PS[A0] including DRAMs 332 connected to CA 324, with chip selects CS[AA0] for the front devices and CS[AA1] for the back devices. DRAMs 332 connect to data bus 382 through DBs 352. Channel A includes PS[A1] including DRAMs 336 connected to CA 322, with chip selects CS[AB0] for the front devices and CS[AB1] for the back devices. DRAMs 336 connect to data bus 382 through DBs 352, where DBs 352 share DQ[A0] of PS[A0] and DQ[A1] of PS[A1].

Channel A includes PS[A2] including DRAMs 334 connected to CA 324, sharing the CA bus with DRAMs 332 of PS[A0], with chip selects CS[AA2] for the front devices and CS[AA3] for the back devices. DRAMs 334 connect to data bus 382 through DBs 354. Channel A includes PS[A3] including DRAMs 338 connected to CA 322, sharing the CA bus with DRAMs 336 of PS[A1], with chip selects CS[AB2] for the front devices and CS[AB3] for the back devices. DRAMs 338 connect to data bus 382 through DBs 354, where DBs 262 share DQ[A2] of PS[A2] and DQ[A3] of PS[A3].

It will be observed that DIMM 310 includes additional chip selects to enable selecting front and back devices to share a data bus connection through the data buffers. Being able to select the front and back devices separately within the pseudo channels enables system 300 to access different groups of devices as bank groups within the pseudo channels, which can reduce the bandwidth limitations, as the host controller can account for independent access to different DRAMs within the pseudo channels.

Channel B includes PS[B0] including DRAMs 342 connected to CA 328, with chip selects CS[BA0] for the front devices and CS[BA1] for the back devices. DRAMs 342 connect to data bus 384 through DBs 362. Channel B includes PS[B1] including DRAMs 346 connected to CA 326, with chip selects CS[BB0] for the front devices and CS[BB1] for the back devices. DRAMs 346 connect to data bus 384 through DBs 362, where DBs 362 share DQ[B0] of PS[B0] and DQ[B1] of PS[B1].

Channel B includes PS[B2] including DRAMs 344 connected to CA 328, sharing the CA bus with DRAMs 342 of PS[B0], with chip selects CS[BA2] for the front devices and CS[BA3] for the back devices. DRAMs 344 connect to data bus 384 through DBs 364. Channel B includes PS[B3] including DRAMs 348 connected to CA 326, sharing the CA bus with DRAMs 346 of PS[B1], with chip selects CS[BB2] for the front devices and CS[BB3] for the back devices. DRAMs 348 connect to data bus 384 through DBs 364, where DBs 364 share DQ[B2] of PS[B2] and DQ[B3] of PS[B3].

DIMM 310 includes BCOM bus 350 for DBs 352 and DBs 354 and BCOM bus 360 for DBs 362 and DB 364. RCD 320 can receive multiple signals from the host, including clock (CLK) 376, which represents a clock or timing signal for the commands from the host to RCD 320. The data buses can have their own clock signals (e.g., DQS or data strobe), which are not specifically shown. RCD 320 can receive CA 372, the CA bus from the host for Channel A, and CA 374, the CA bus from the host for Channel B.

Similar to system 200, the data bus connections through the DBs can include a DM pin per byte of data (DQ) pins. The DM pin can allow the DRAMs to provide ECC information in response to a read command. The ECC information can be exchanged through the internal on-die ECC circuitry.

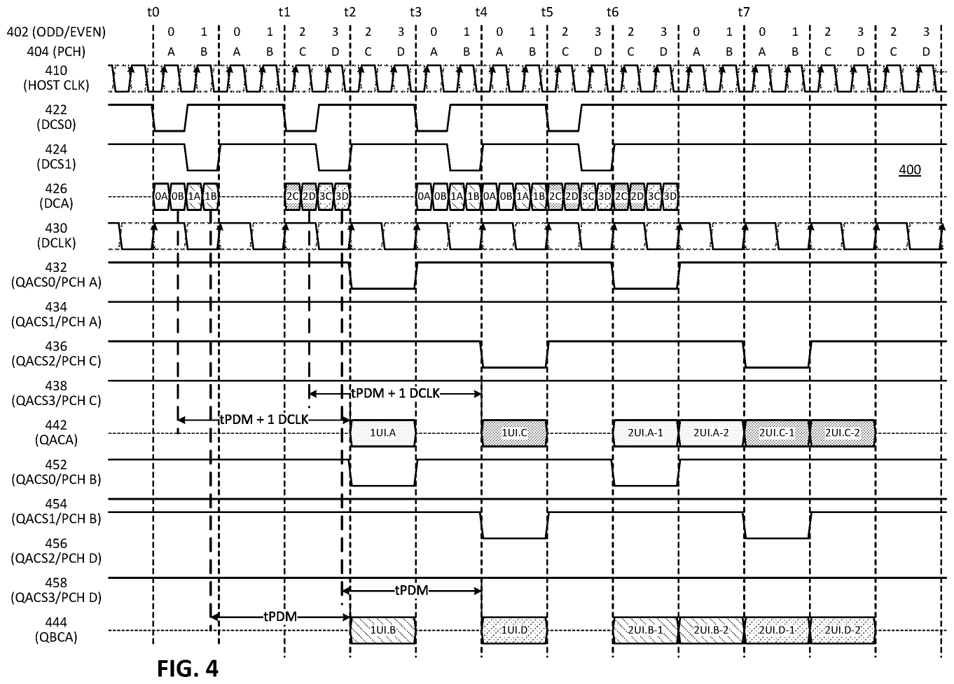

FIG. 4 is a block diagram of an example of data timing for a system with pseudo channels. Diagram 400 represents a timing diagram that illustrates the command timing for a system in accordance with an example of system 200. Diagram 400 illustrates an example of a pseudo-BL32 mode for a 1N mode. Doubling the burst length can eliminate command bandwidth limitations in the 1N mode of operation. The host must just ensure it does not violate any DRAM timings. The memory controller manages the scheduling to avoid timing violations.

With the structural/architectural diagrams above, ‘A’ and ‘B’ referred to the different memory subchannels, while the different pseudo channels were identified as ‘0’, ‘1’, ‘2’, and ‘3’. Diagram 400 includes an indication of odd and even cycles, with the four pseudo channels identified as ‘A’, ‘B’, ‘C’, and ‘D’. Diagram 400 represents the command signaling and timing for a single subchannel.

Indication 402 represents an indication of odd/even timeslots in which the host controller can schedule. Indications of ‘0’, ‘1’, ‘2’, and ‘3’ represent slots in which commands can be sent for the four different PCHs. Indication 404 indicates the PCHs that can be addressed in the different odd/even timeslots. It will be understood that the PCHs can be multiplexed within an odd/even timeslot.

Signal 410 represents the host clock (CLK). Signal 422 represents a chip select signal DCS0 and signal 424 represents a chip select signal DCS1. The chip selects signals are represented as asserted low, but could alternatively be asserted high in a different implementation. The ‘D’ preceding the chip select reference indicates that it is the host side signal going from the host to the DIMM.

Signal 430 represents a command signal from the host to the DIMM, which could be indicated as DCA[6:0] for a DDR5 implementation having 7 command/address signal lines. The signal can also include a parity signal line DPAR. Signal 430 represents a clock signal provided to the DIMM, DCLK.

Signal 432 represents an RCD to DRAM chip select QACS0 for PCH A. Signal 434 represents an RCD to DRAM chip select QACS1 for PCH A. Signal 436 represents an RCD to DRAM chip select QACS2 for PCH C. Signal 438 represents an RCD to DRAM chip select QACS3 for PCH C. Diagram 400 represents a 1N mode without back side DRAMs, and thus, signal 434 and signal 438 are not asserted in diagram 400. Signal 442 represents a command signal for the command bus for PCH A and PCH C, QACA.

Signal 452 represents an RCD to DRAM chip select QACS0 for PCH B. Signal 454 represents an RCD to DRAM chip select QACS1 for PCH B. Signal 456 represents an RCD to DRAM chip select QACS2 for PCH D. Signal 458 represents an RCD to DRAM chip select QACS3 for PCH D. Since diagram 400 represents a 1N mode without back side DRAMs, signal 454 and signal 458 are not asserted in diagram 400. Signal 444 represents a command signal for the command bus for PCH B and PCH D, QBCA.

Referring again to signal 426, the host can assert commands at time t0 for PCH A, with the signal representing a two-UI command with 0A and 0B, followed by a two-UI command for PCH B, represented by 1A and 1B. In one example, there is a minimum delay, tPDM, between the commands on the host CA bus and the internal commands to the DRAMs. The delay tPDM can be, for example, as used in JESD82-511, DDR5 Registering Clock Driver Definition (DDR5RCD01), originally released by JEDEC in August 2021. The first instances of commands represent an access command, such as a read command or a write command.

In response to the command for PCH A, signal 442 illustrates an internal command from the RCD to the DRAM devices of PCH A, with command 1UI.A at time t2. To align the command to the clock, the RCD can send 1UI.A tPDM+1 DCLK after the second cycle of the command, 0B. Likewise, in response to the command for PCH B, signal 444 illustrates an internal command from the RCD to the DRAM device of PCH B, with command 1UI.B, also at time t2. It will be observed that the RCD can issue 1UI.B after tPDM from 1B, which aligns the command with the clock at t2.

Diagram 400 also illustrates host commands at time t1 for PCH C and PCH D. Signal 426 illustrates that the host can assert commands for PCH C, with the signal representing a two-UI command with 2C and 2D, followed by a two-UI command for PCH D, represented by 3C and 3D. Seeing that the DCLK cycle after commands 0A, 0B, 1A, and 1B are also scheduled for A and B commands, the host can wait until t1, when the memory controller can schedule commands for PCH C and PCH D, as represented by indication 402 and indication 404. Again, the commands represent an access command, such as a read command or a write command.

In response to the command for PCH C, signal 442 illustrates an internal command from the RCD to the DRAM devices of PCH C, with command 1UI.C at time t4, a delay of tPDM+1 DCLK after the second cycle of the command, 2D. Likewise, in response to the command for PCH D, signal 444 illustrates an internal command from the RCD to the DRAM device of PCH D, with command 1UI.D, also at time t4, a delay of tPDM from 3D. Again, with the difference of 1 DCLK, the clock can align the timing of the commands for PCH C and PCH D at t4.

Signal 426 illustrates additional host commands at time t3, where 0A and 0B represent a 2-UI CAS command for PCH A, followed by 1A and 1B as a 2-UI command for PCH B. In one example, at time t4, the host can issue a second CAS command for PCH A with the additional 0A and 0B, and a second CAS command for PCH B with the additional 1A and 1B. In response to the first CAS command, signal 442 illustrates 2UI.A-1 at time t6, which represents the first of two internal CAS commands for PCH A. In one example, the host issues the second CAS command for PCH A, at time t4, and in response to the second CAS command the RCD can issue 2UI.A-2. In one example, the host does not issue the second CAS command, and the RCD issues both 2UI.A-1 and 2UI.A-2 in response to the CAS command at t3.

Similarly, in response to the first CAS command for PCH B, signal 444 illustrates 2UI.B-1 at time t6, which represents the first of two internal CAS commands for PCH B. In one example, the host issues the second CAS command for PCH B, at time t4, and in response to the second CAS command the RCD can issue 2UI.B-2. In one example, the host does not issue the second CAS command, and the RCD issues both 2UI.B-1 and 2UI.B-2 in response to the CAS command at t3.

Signal 426 illustrates additional host commands at time t5, where 2C and 2D represent a 2-UI CAS command for PCH C, followed by 3C and 3D as a 2-UI command for PCH D. In one example, at time t6, the host can issue a second CAS command for PCH C with the additional 2C and 2D, and a second CAS command for PCH D with the additional 3C and 3D. In response to the first CAS command, signal 442 illustrates 2UI.C-1 at time t7, which represents the first of two internal CAS commands for PCH C. In one example, the host issues the second CAS command for PCH C, at time t6, and in response to the second CAS command the RCD can issue 2UI.C-2. In one example, the host does not issue the second CAS command, and the RCD issues both 2UI.C-1 and 2UI.C-2 in response to the CAS command at t5.

Similarly, in response to the first CAS command for PCH D, signal 444 illustrates 2UI.D-1 at time t7, which represents the first of two internal CAS commands for PCH D. In one example, the host issues the second CAS command for PCH D, at time t6, and in response to the second CAS command the RCD can issue 2UI.D-2. In one example, the host does not issue the second CAS command, and the RCD issues both 2UI.D-1 and 2UI.D-2 in response to the CAS command at t5.

The second CAS commands of signal 442 and signal 444 can enable the system to achieve a BL32 mode for data transfer between the host and the memory devices. Diagram 400 illustrates a way to address 4 separate pseudo channels. In one example, diagram 400 would be different for a 2N mode, where the system would utilize additional CS signals for the 2N mode. As with the 1N mode, the RCD can issue a second CAS command either in response to a second CAS command from the host, or can issue two CAS commands in response to a single CAS command from the host.

In one implementation of a 2N mode, the 2 CAS commands per cacheline access can prevent the host from having sufficient command bandwidth to obtain the theoretical 100% peak bandwidth. To avoid the lack of command bandwidth, in one example, the system can have a new mode where the host side runs at 2N mode, while the backside remains at 1N mode. In such a mode, the host sends only a single CAS command to the RCD, and the RCD is then responsible to keep track of the CAS command temporarily, and automatically increment the column address to issue the second CAS to the DRAM. With the RCD providing the second CAS command, the host and the DRAMs can exchange a full cacheline. The gap between the first CAS command and the second CAS command can be determined by the tCCD_L timing parameter specified by the JEDEC DDR5 specification. The memory controller can be configured to account for the RCD issuing the second CAS command to ensure no violation occurs and it does not send a DRAM command to the target PCH when the RCD is busy issuing the second CAS command on the backside between the RCD and the DRAMs.

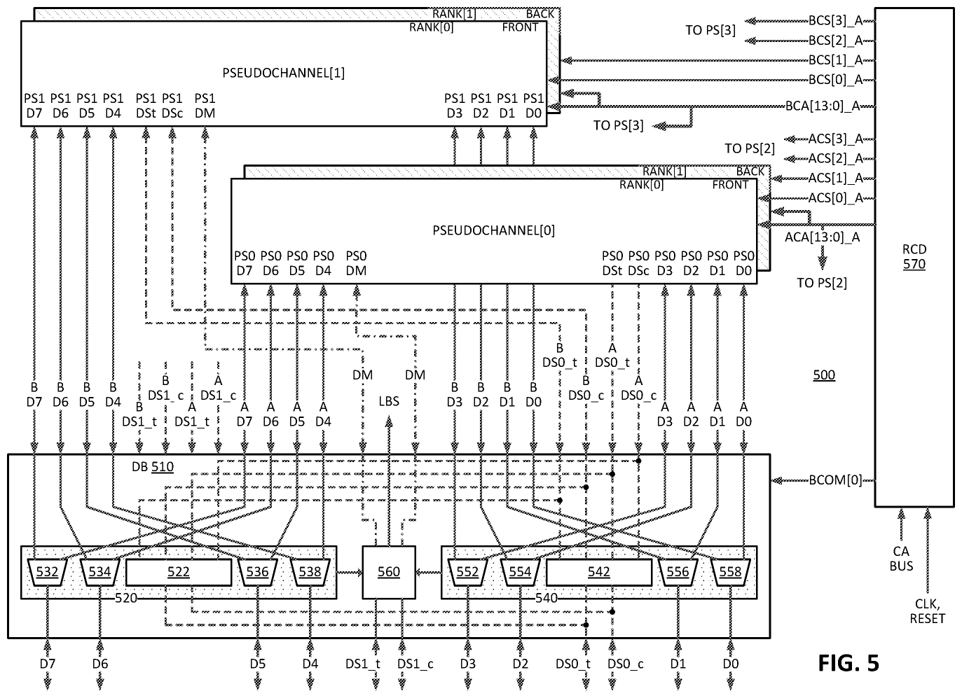

FIG. 5 is a block diagram of an example of signaling for a memory module with pseudo channels. System 500 represents a memory module system in accordance with an example of system 100 or system 300. System 500 includes memory devices of different pseudo channels coupled to a data buffer.

Pseudochannel[0] (referred to as PS[0] for simplicity, and alternatively referred to as PCH 0) represents DRAM devices (e.g., front and back devices) for Rank[0] and Rank[1] devices of a first pseudo channel. Pseudochannel[1] (referred to as PS[1] for simplicity, and alternatively referred to as PCH 1) represents DRAM devices for Rank[0] and Rank[1] of a second pseudo channel. As illustrated, the DRAM devices are ×8 devices, having 8 data interface signals. In an alternate implementation, the system can have ×16 DRAM devices. PS[0] includes data interfaces PS0[D7:D0] and PS[1] includes data interfaces PS1[D7:D0].

The DRAM devices also include interfaces for clock or timing signals, identified as DS_t (data strobe signal) and DS_c (data strobe complement) on the data buffer side and DSt and DSc, respectively, internally to the pseudo channel blocks. System 500 also illustrates a data mask (DM) signal between each pseudo channel and data buffer (DB) 510.

DB 510 represents a data buffer in accordance with any example herein. In one example, DB 510 includes interface hardware 520 with retimer 522 to manage the synchronization of the clock signal from the host bus with the timing signals on the memory module for data signals D[7:4] of the host data bus with associated data strobe DS1_t and DS1_c. In one example, DB 510 includes interface hardware 540 with retimer 542 to manage the synchronization of the clock signal from the host bus with the timing signals on the memory module for data signals D[3:0] of the host data bus with associated data strobe DS0_t and DS0_c.

System 500 illustrates a configuration for four pseudo channels, with the details only for two pseudo channels, to simplify the diagram. It will be observed that DS1_t and DS1_c are illustrated with respect to DB 510, while the connection to the pseudo channels is not illustrated. These signals can be connected to the back devices.

In one example, interface hardware 520 includes mux (multiplexer) 532 to select D7 between PS[0] and PS[1], mux 534 to select D6 between PS[0] and PS[1], mux 536 to select D5 between PS[0] and PS[1], and mux 538 to select D4 between PS[0] and PS[1]. In one example, interface hardware 540 includes mux (multiplexer) 552 to select D3 between PS[0] and PS[1], mux 554 to select D2 between PS[0] and PS[1], mux 556 to select D1 between PS[0] and PS[1], and mux 558 to select D0 between PS[0] and PS[1].

In one example, system 500 can have front and back devices share DB 510, where the front and back devices have data interfaces to the same data signal lines of the data buffer. The system can select the back devices with additional multiplexing.

System 500 illustrates BCOM[0], which represents a buffer communication channel for RCD 570 to provide commands/control to DB 510. BCOM[0] enables RCD 570 to specify the timing for data exchange with the different pseudo channels.

System 500 illustrates eight pseudo channel chip select lines, two for each pseudo channel. The two different select lines enable separate selection of front devices and back devices. In one example, RCD 570 selects the front device of PS[0] with ACS[0]_A and the back device of PS[0] with ACS[1]_A. In one example, RCD 570 selects the front device of PS[1] with BCS[0]_A and the back device of PS[1] with BCS[1]_A. In one example, RCD 570 selects the devices of PS[2] (alternatively, PCH 2) with ACS[2]_A and ACS[3]_A. In one example, RCD 570 selects the devices of PS[3] (alternatively, PCH 3) with BCS[2]_A and BCS[3]_A. In one example, RCD 570 provides CA bus ACA[13:0]_A to PS[0] and PS[2]. In one example, RCD 570 provides CA bus BCA[13:0]_A to PS[1] and PS[3].

RCD 570 can receive CA bus from the host as well as CLK (clock) and RESET signals. It will be understood that system 500 illustrates more CS pins on the backside of RCD 570 than what will be received on the frontside from the host.

In one example, system 500 provides the ability to provide ECC bits from the four pseudo channels. Instead of having a dedicated ECC device in the rank, the devices of the different pseudo channels can expose pre-existing internal on-die ECC (OD-ECC) bits from the same device the cacheline is in. System 500 illustrates the use of the DM signal pins to provide the OD-ECC bits without needing dedicated pins for ECC.

The DM signal, which can be referred to as DMI, is traditionally provided to the DRAMs from the host only on write commands. The DM signal pin can be shared with the TDQS function, enabling the memory device to terminate. In one example, the internal circuitry connected to the DM/TDQS_t pin can be modified to include a data transceiver to send ECC information to the host and receive ECC bits from the host. In one example, the DM signal can be used for sending/receiving ECC information as well as for cyclic redundancy check (CRC) information. More specifically, half the time the pin can be used for sending/receiving ECC, and the other half the time can be used for CRC.

In one example, DB 510 includes logic 560, which can represent retimer logic in the data buffer. Logic 560 can receive DS1_t and DS1_c from the host and provide DM signals in the DRAM side. In one example, logic 560 can receive information from interface hardware 520 and interface hardware 540, such as timing signals. In one example, logic 560 generates LBS, which represents an alert signal for the DIMM.

Use of the DM pin enables MRDIMMs to provide 32 bits of ECC data per 64 byte cache line. In one example, the DRAMs disable their internal generation and checking and provide the 8 bits per 128 data bits to the host via the DM pin. The host can likewise provide the 8 bits of ECC per 128 data bits on write. In one example, the DRAM devices can store the ECC information internally as they normally would for internal ECC, only the ECC information can be exchanged with the host.

In one example, for each BL16 transfer, the first 8UI contain ECC bits with the second 8UI unused. Note that system 500 illustrates two additional pins per data buffer on the DRAM side to accommodate the exchange of ECC information. To transfer the ECC data to/from the host, the second DQS pair can be used as a differential data bit. In one example, the differential pin can be used for the CRC.

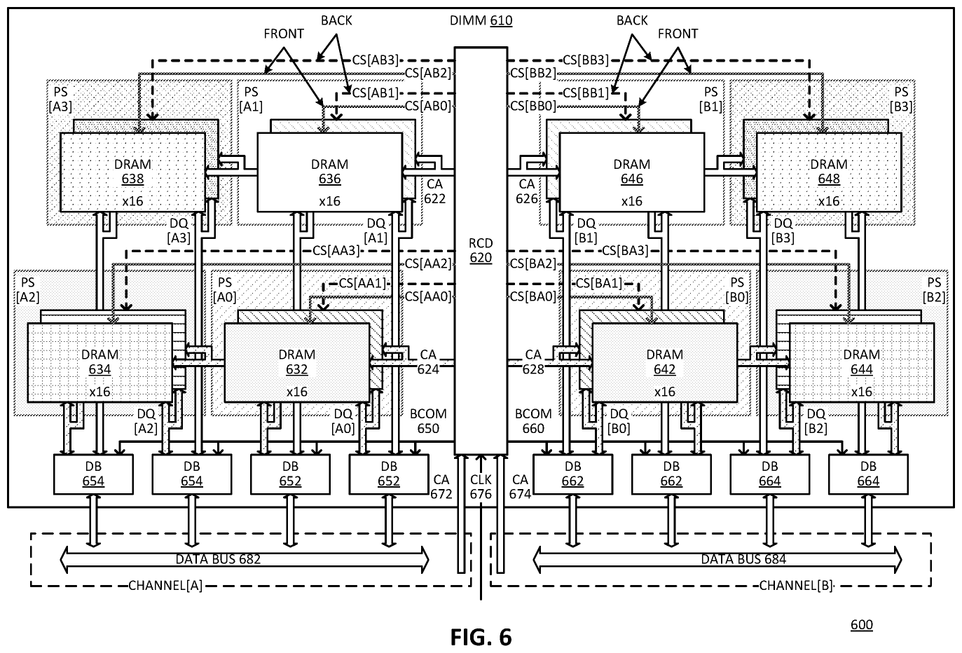

FIG. 6 is a block diagram of an example of an LRDIMM with four pseudo channels per channel with ×16 devices and additional chip selects. System 600 represents a system in accordance with an example of system 100. System 600 represents a ×16 device alternative to an example of system 300 of FIG. 3. In the example of system 600, the two bytes of the ×16 device are connected to different data buffers, and shared with a byte of another ×16 device.

System 600 illustrates DIMM 610 with RCD 620 to manage commands from the host to the DRAM devices, and to control the operation of the data buffers for the exchange of data. System 600 illustrates DIMM 610 having 4 pseudo channels with front-side devices and backside devices.

Channel A includes PS[A0] including DRAMs 632 connected to CA 624, with chip selects CS[AA0] for the front devices and CS[AA1] for the back devices. DRAMs 632 connect to data bus 682 through DBs 652, with half of each device coupled to each of the two DBs. Channel A includes PS[A1] including DRAMs 636 connected to CA 622, with chip selects CS[AB0] for the front devices and CS[AB1] for the back devices. DRAMs 636 connect to data bus 682 through DBs 652, with half of each device coupled to each of the two DBs, where DBs 252 share DQ[A0] of PS[A0] and DQ[A1] of PS[A1].

Channel A includes PS[A2] including DRAMs 634 connected to CA 624, sharing the CA bus with DRAMs 632 of PS[A0], with chip selects CS[AA2] for the front devices and CS[AA3] for the back devices. DRAMs 634 connect to data bus 682 through DBs 654, with half of each device coupled to each of the two DBs. Channel A includes PS[A3] including DRAMs 638 connected to CA 622, sharing the CA bus with DRAMs 636 of PS[A1], with chip selects CS[AB2] for the front devices and CS[AB3] for the back devices. DRAMs 638 connect to data bus 682 through DBs 654, with half of each device coupled to each of the two DBs, where DBs 262 share DQ[A2] of PS[A2] and DQ[A3] of PS[A3].

It will be observed that DIMM 610 includes additional chip selects to enable selecting front and back devices to share a data bus connection through the data buffers. Being able to select the front and back devices separately within the pseudo channels enables system 600 to access different groups of devices as bank groups within the pseudo channels, which can reduce the bandwidth limitations, as the host controller can account for independent access to different DRAMs within the pseudo channels.

Channel B includes PS[B0] including DRAMs 642 connected to CA 628, with chip selects CS[BA0] for the front devices and CS[BA1] for the back devices. DRAMs 642 connect to data bus 684 through DBs 662, with half of each device coupled to each of the two DBs. Channel B includes PS[B1] including DRAMs 646 connected to CA 626, with chip selects CS[BB0] for the front devices and CS[BB1] for the back devices. DRAMs 646 connect to data bus 684 through DBs 662, with half of each device coupled to each of the two DBs, where DBs 662 share DQ[B0] of PS[B0] and DQ[B1] of PS[B1].

Channel B includes PS[B2] including DRAMs 644 connected to CA 628, sharing the CA bus with DRAMs 642 of PS[B0], with chip selects CS[BA2] for the front devices and CS[BA3] for the back devices. DRAMs 644 connect to data bus 684 through DBs 664, with half of each device coupled to each of the two DBs. Channel B includes PS[B3] including DRAMs 648 connected to CA 626, sharing the CA bus with DRAMs 646 of PS[B1], with chip selects CS[BB2] for the front devices and CS[BB3] for the back devices. DRAMs 648 connect to data bus 684 through DBs 664, with half of each device coupled to each of the two DBs, where DBs 664 share DQ[B2] of PS[B2] and DQ[B3] of PS[B3].

DIMM 610 includes BCOM bus 650 for DB 652 and DB 654 and BCOM bus 660 for DB 662 and DB 664. RCD 620 can receive multiple signals from the host, including clock (CLK) 676, which represents a clock or timing signal for the commands from the host to RCD 620. The data buses can have their own clock signals (e.g., DQS or data strobe), which are not specifically shown. RCD 620 can receive CA 672, the CA bus from the host for Channel A, and CA 674, the CA bus from the host for Channel B.

As with system 300, the data bus connections through the DBs can include a DM pin per byte of data (DQ) pins. The DM pin can allow the DRAMs to provide ECC information in response to a read command. The ECC information can be exchanged through the internal on-die ECC circuitry.

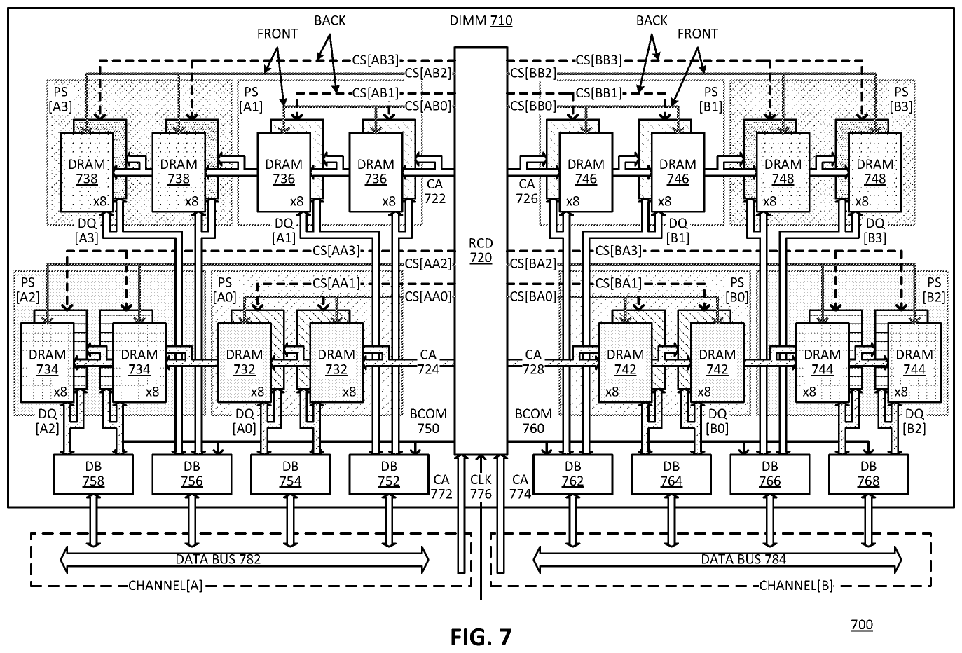

FIG. 7 is a block diagram of an example of an LRDIMM with four pseudo channels per channel with ×8 devices and same-PCH buffer multiplexing. System 700 represents a system in accordance with an example of system 100. System 700 represents ×8 devices as an alternative to an example of system 300 of FIG. 3. In the example of system 700, the two devices of a pseudo channel share a data buffer instead of sharing the data buffer with devices of a different pseudo channel.

System 700 illustrates DIMM 710 with RCD 720 to manage commands from the host to the DRAM devices, and to control the operation of the data buffers for the exchange of data. System 700 illustrates DIMM 710 having 4 pseudo channels with front-side devices and backside devices.

Channel A includes PS[A0] including DRAMs 732 connected to CA 724, with chip selects CS[AA0] for the front devices and CS[AA1] for the back devices. DRAMs 732 connect to data bus 782 through DB 754. Channel A includes PS[A1] including DRAMs 736 connected to CA 722, with chip selects CS[AB0] for the front devices and CS[AB1] for the back devices. DRAMs 736 connect to data bus 782 through DB 752. In system 700, DB 752 can be responsible for DQ[A1] of PS[A1] and DB 754 can be responsible for DQ[A0] of PS[A0].

Channel A includes PS[A2] including DRAMs 734 connected to CA 724, sharing the CA bus with DRAMs 732 of PS[A0], with chip selects CS[AA2] for the front devices and CS[AA3] for the back devices. DRAMs 734 connect to data bus 782 through DB 758. Channel A includes PS[A3] including DRAMs 738 connected to CA 722, sharing the CA bus with DRAMs 736 of PS[A1], with chip selects CS[AB2] for the front devices and CS[AB3] for the back devices. DRAMs 738 connect to data bus 782 through DB 756. In system 700, DB 756 can be responsible for DQ[A3] of PS[A3] and DB 758 can be responsible for DQ[A2] of PS[A2].

It will be observed that DIMM 710 includes additional chip selects to enable selecting front and back devices to share a data bus connection through the data buffers. Being able to select the front and back devices separately within the pseudo channels enables system 700 to access different groups of devices as bank groups within the pseudo channels, which can reduce the bandwidth limitations, as the host controller can account for independent access to different DRAMs within the pseudo channels.

Channel B includes PS[B0] including DRAMs 742 connected to CA 728, with chip selects CS[BA0] for the front devices and CS[BA1] for the back devices. DRAMs 742 connect to data bus 784 through DB 764. Channel B includes PS[B1] including DRAMs 746 connected to CA 726, with chip selects CS[BB0] for the front devices and CS[BB1] for the back devices. DRAMs 746 connect to data bus 784 through DB 762. In system 700, DB 762 can be responsible for DQ[B1] of PS[B1] and DB 754 can be responsible for DQ[B0] of PS[B0].

Channel B includes PS[B2] including DRAMs 744 connected to CA 728, sharing the CA bus with DRAMs 742 of PS[B0], with chip selects CS[BA2] for the front devices and CS[BA3] for the back devices. DRAMs 744 connect to data bus 784 through DB 768. Channel B includes PS[B3] including DRAMs 748 connected to CA 726, sharing the CA bus with DRAMs 746 of PS[B1], with chip selects CS[BB2] for the front devices and CS[BB3] for the back devices. DRAMs 748 connect to data bus 784 through DB 766. In system 700, DB 766 can be responsible for DQ[B3] of PS[B3] and DB 768 can be responsible for DQ[B2] of PS[B2].

DIMM 710 includes BCOM bus 750 for DB 752, DB 754, DB 756, and DB 758 and BCOM bus 760 for DB 762, DB 764, DB 766, and DB 768. RCD 720 can receive multiple signals from the host, including clock (CLK) 776, which represents a clock or timing signal for the commands from the host to RCD 720. The data buses can have their own clock signals (e.g., DQS or data strobe), which are not specifically shown. RCD 720 can receive CA 772, the CA bus from the host for Channel A, and CA 774, the CA bus from the host for Channel B.

As with system 300, the data bus connections through the DBs can include a DM pin per byte of data (DQ) pins. The DM pin can allow the DRAMs to provide ECC information in response to a read command. The ECC information can be exchanged through the internal on-die ECC circuitry.

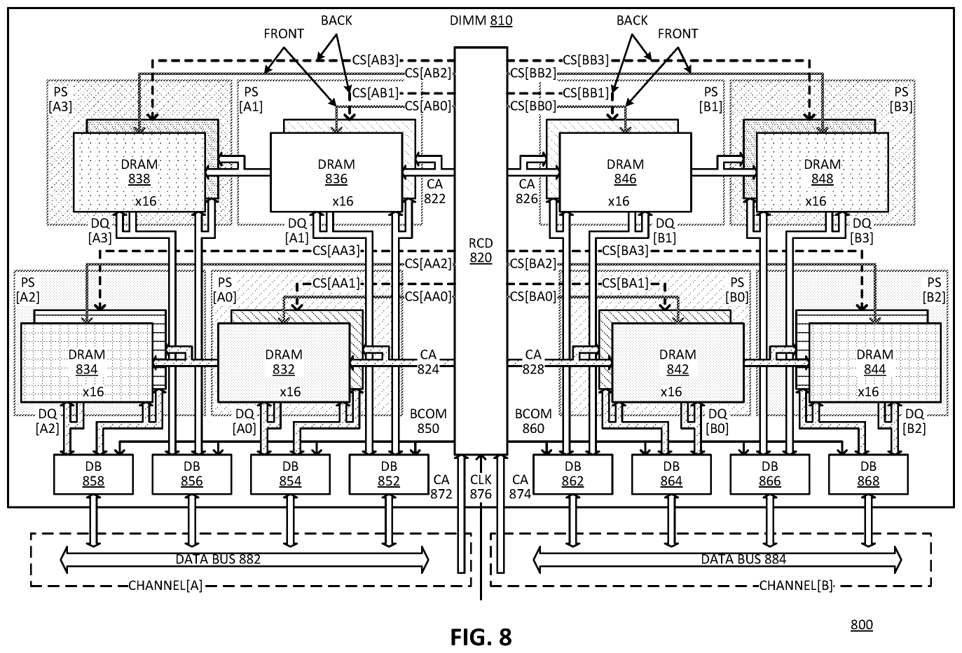

FIG. 8 is a block diagram of an example of an LRDIMM with four pseudo channels per channel with ×16 devices on two sides and same-PCH buffer multiplexing. System 800 represents a system in accordance with an example of system 100. System 800 represents a ×16 device alternative to an example of system 700 of FIG. 7. In the example of system 800, the two bytes of the ×16 device are connected to a single data buffer.

System 800 illustrates DIMM 810 with RCD 820 to manage commands from the host to the DRAM devices, and to control the operation of the data buffers for the exchange of data. System 800 illustrates DIMM 810 having 4 pseudo channels with front-side devices and backside devices.

Channel A includes PS[A0] including DRAMs 832 connected to CA 824, with chip selects CS[AA0] for the front devices and CS[AA1] for the back devices. DRAMs 832 connect to data bus 882 through DB 854. Channel A includes PS[A1] including DRAMs 836 connected to CA 822, with chip selects CS[AB0] for the front devices and CS[AB1] for the back devices. DRAMs 836 connect to data bus 882 through DB 852. In system 800, DB 852 can be responsible for DQ[A1] of PS[A1] and DB 854 can be responsible for DQ[A0] of PS[A0].

Channel A includes PS[A2] including DRAMs 834 connected to CA 824, sharing the CA bus with DRAMs 832 of PS[A0], with chip selects CS[AA2] for the front devices and CS[AA3] for the back devices. DRAMs 834 connect to data bus 882 through DB 858. Channel A includes PS[A3] including DRAMs 838 connected to CA 822, sharing the CA bus with DRAMs 836 of PS[A1], with chip selects CS[AB2] for the front devices and CS[AB3] for the back devices. DRAMs 838 connect to data bus 882 through DB 856. In system 800, DB 856 can be responsible for DQ[A3] of PS[A3] and DB 858 can be responsible for DQ[A2] of PS[A2].

It will be observed that DIMM 810 includes additional chip selects to enable selecting front and back devices to share a data bus connection through the data buffers. Being able to select the front and back devices separately within the pseudo channels enables system 800 to access different groups of devices as bank groups within the pseudo channels, which can reduce the bandwidth limitations, as the host controller can account for independent access to different DRAMs within the pseudo channels.

Channel B includes PS[B0] including DRAMs 842 connected to CA 828, with chip selects CS[BA0] for the front devices and CS[BA1] for the back devices. DRAMs 842 connect to data bus 884 through DB 864. Channel B includes PS[B1] including DRAMs 846 connected to CA 826, with chip selects CS[BB0] for the front devices and CS[BB1] for the back devices. DRAMs 846 connect to data bus 884 through DB 862. In system 800, DB 862 can be responsible for DQ[B1] of PS[B1] and DB 864 can be responsible for DQ[B0] of PS[B0].

Channel B includes PS[B2] including DRAMs 844 connected to CA 828, sharing the CA bus with DRAMs 842 of PS[B0], with chip selects CS[BA2] for the front devices and CS[BA3] for the back devices. DRAMs 844 connect to data bus 884 through DB 868. Channel B includes PS[B3] including DRAMs 848 connected to CA 826, sharing the CA bus with DRAMs 846 of PS[B1], with chip selects CS[BB2] for the front devices and CS[BB3] for the back devices. DRAMs 848 connect to data bus 884 through DB 866. In system 800, DB 866 can be responsible for DQ[B3] of PS[B3] and DB 868 can be responsible for DQ[B2] of PS[B2].

DIMM 810 includes BCOM bus 850 for DB 852, DB 854, DB 856, and DB 858 and BCOM bus 860 for DB 862, DB 864, DB 866, and DB 868. RCD 820 can receive multiple signals from the host, including clock (CLK) 876, which represents a clock or timing signal for the commands from the host to RCD 820. The data buses can have their own clock signals (e.g., DQS or data strobe), which are not specifically shown. RCD 820 can receive CA 872, the CA bus from the host for Channel A, and CA 874, the CA bus from the host for Channel B.

As with system 700, the data bus connections through the DBs can include a DM pin per byte of data (DQ) pins. The DM pin can allow the DRAMs to provide ECC information in response to a read command. The ECC information can be exchanged through the internal on-die ECC circuitry.

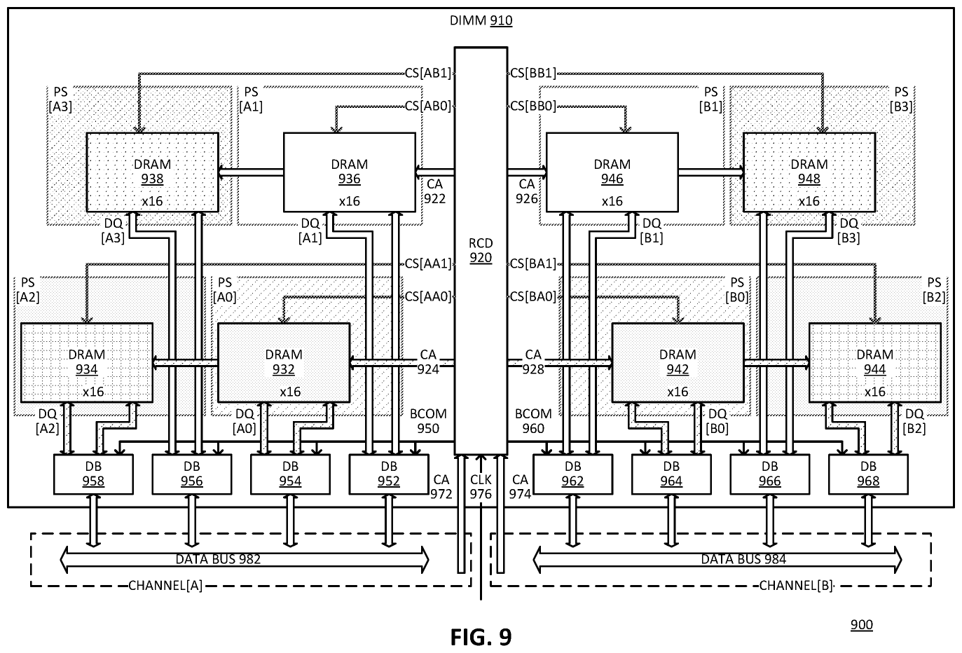

FIG. 9 is a block diagram of an example of an LRDIMM with four pseudo channels per channel with ×16 devices on one side and same-PCH buffer multiplexing. System 900 represents a system in accordance with an example of system 100. System 900 represents an alternative to an example of system 800 of FIG. 8. In the example of system 900, each ×16 device has a dedicated MR DB. System 900 has reduced density relative to system 800, and therefore does not need additional chip selects.

System 900 illustrates DIMM 910 with RCD 920 to manage commands from the host to the DRAM devices, and to control the operation of the data buffers for the exchange of data. System 900 illustrates DIMM 910 having 4 pseudo channels with front-side devices and backside devices.

Channel A includes PS[A0] including DRAM 932 connected to CA 924, with chip select CS[AA0]. DRAM 932 connects to data bus 982 through DB 954. Channel A includes PS[A1] including DRAM 936 connected to CA 922, with chip select CS[AB0]. DRAM 936 connects to data bus 982 through DB 952. In system 900, DB 952 can be responsible for DQ[A1] of PS[A1] and DB 954 can be responsible for DQ[A0] of PS[A0].

Channel A includes PS[A2] including DRAM 934 connected to CA 924, sharing the CA bus with DRAM 932 of PS[A0], with chip select CS[AA1]. DRAM 934 connects to data bus 982 through DB 958. Channel A includes PS[A3] including DRAM 938 connected to CA 922, sharing the CA bus with DRAM 936 of PS[A1], with chip select CS[AB1]. DRAM 938 connects to data bus 982 through DB 956. In system 900, DB 956 can be responsible for DQ[A3] of PS[A3] and DB 958 can be responsible for DQ[A2] of PS[A2].

Channel B includes PS[B0] including DRAM 942 connected to CA 928, with chip select CS[BA0]. DRAM 942 connects to data bus 984 through DB 964. Channel B includes PS[B1] including DRAM 946 connected to CA 926, with chip select CS[BB0]. DRAM 946 connects to data bus 984 through DB 962. In system 900, DB 962 can be responsible for DQ[B1] of PS[B1] and DB 964 can be responsible for DQ[B0] of PS[B0].

Channel B includes PS[B2] including DRAM 944 connected to CA 928, sharing the CA bus with DRAM 942 of PS[B0], with chip select CS[BA1]. DRAM 944 connects to data bus 984 through DB 968. Channel B includes PS[B3] including DRAM 948 connected to CA 926, sharing the CA bus with DRAM 946 of PS[B1], with chip select CS[BB1]. DRAM 948 connects to data bus 984 through DB 966. In system 900, DB 966 can be responsible for DQ[B3] of PS[B3] and DB 968 can be responsible for DQ[B2] of PS[B2].

DIMM 910 includes BCOM bus 950 for DB 952, DB 954, DB 956, and DB 958 and BCOM bus 960 for DB 962, DB 964, DB 966, and DB 968. RCD 920 can receive multiple signals from the host, including clock (CLK) 976, which represents a clock or timing signal for the commands from the host to RCD 920. The data buses can have their own clock signals (e.g., DQS or data strobe), which are not specifically shown. RCD 920 can receive CA 972, the CA bus from the host for Channel A, and CA 974, the CA bus from the host for Channel B.

As with system 800, the data bus connections through the DBs can include a DM pin per byte of data (DQ) pins. The DM pin can allow the DRAMs to provide ECC information in response to a read command. The ECC information can be exchanged through the internal on-die ECC circuitry.

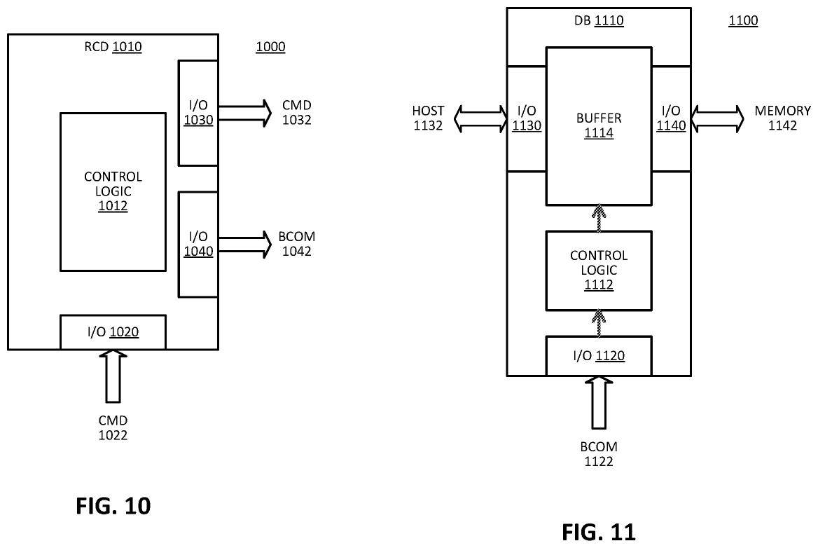

FIG. 10 is a block diagram of an example of a registered clock driver. System 1000 represents an RCD in accordance with system 100. RCD 1010 can be a controller for a DIMM or other memory module having data buffers. RCD 1010 includes I/O (input/output) 1020, which represents a hardware interface to a command bus, represented by CMD (command) 1022. I/O 1020 enables RCD 1010 to receive commands from the host or memory controller.

RCD 1010 includes I/O 1030, which represents a hardware interface to a command bus, represented by CMD (command) 1032, over which RCD 1010 can send commands to memory devices on the memory module. RCD 1010 includes I/O 1040, which represents a hardware interface to a BCOM bus, represented by BCOM 1042, over which RCD 1010 can send commands to data buffers on the memory module. Each I/O hardware interface can include signal line interfaces, transmit and/or receive circuitry, and control logic to manage the interface

Control logic 1012 represents logic to enable the operation of RCD 1010. In one example, at least some of control logic 1012 is implemented in hardware. In one example, at least some of control logic 1012 is implemented in firmware/software. In one example, control logic 1012 is implemented in a combination of hardware and software.

In one example, control logic 1012 enables RCD 1010 to manage chip selects and commands to attached pseudo channels. With control logic 1012, RCD 1010 can control the operation of data buffers to control the exchange of data with the memory devices of the pseudo channels.

FIG. 11 is a block diagram of an example of a data buffer. System 1100 represents a data buffer (DB) in accordance with system 100. DB 1110 can buffer data between memory device of a memory module and a host controller. DB 1110 includes I/O 1130, which represents a host-side or host facing hardware interface to a host data bus, represented by host 1132. DB includes I/O 1140, which represents a memory-side or memory facing hardware interface to with memory devices, represented by memory 1142. Buffer 1114 represents the buffer between I/O 1130 and I/O 1140.

DB 1110 includes I/O 1120, which represents a hardware interface to a BCOM bus, represented by BCOM 1122. BCOM 1122 enables DB 1110 to receive commands from an RCD (not specifically shown). Each I/O hardware interface can include signal line interfaces, transmit and/or receive circuitry, and control logic to manage the interface.

Control logic 1112 represents logic to enable the operation of DB 1110. In one example, at least some of control logic 1112 is implemented in hardware. In one example, at least some of control logic 1112 is implemented in firmware/software. In one example, control logic 1112 is implemented in a combination of hardware and software.

In one example, control logic 1112 enables DB 1110 to receive and decode BCOM commands from an RCD. The BCOM commands indicate the timing of data access operations, which directs DB 1110 which side of the data to receive from and which side to transfer to (e.g., from memory side to host side or from host side to memory side), and what the timing of the transfer is. In one example, control logic 1112 enables DB 1110 to multiplex data between different pseudo channels or between data interfaces of a same pseudo channel to enable additional pseudo channels in accordance with any example described. In one example, DB 1110 provides an interface for ECC data in accordance with any example described.

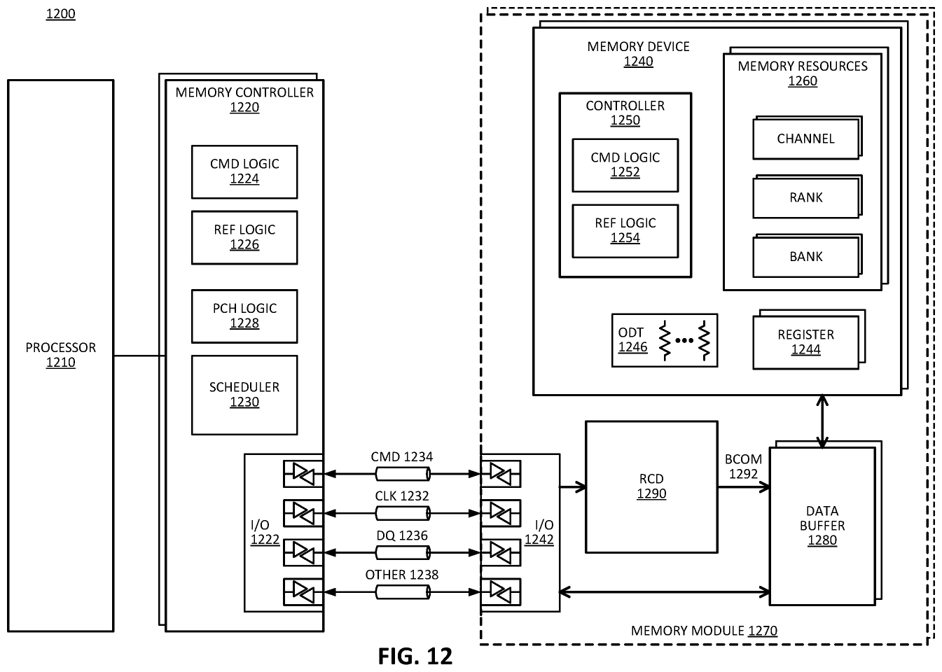

FIG. 12 is a block diagram of an example of a memory subsystem in which pseudo channels can be implemented. System 1200 includes a processor and elements of a memory subsystem in a computing device. System 1200 represents a system in accordance with any example herein of an MRDIMM.

In one example, memory module 1270 includes RCD 1290, which represents a registering clock driver in accordance with any example herein. In one example, memory module 1270 includes data buffers 1280, which represent data buffers in accordance with any example herein. Data buffers 1280 couple to DQ 1236 to buffer data transfer between memory devices 1240 and memory controller 1220. RCD 1290 can control the operation of data buffers 1280 through BCOM 1292. In one example, RCD 1290 manages memory devices 1240 as multiple pseudo channels in accordance with any example herein. PCH logic 1228 in memory controller 1220 represents logic on the host side to manage scheduling and timing for exchanging data with memory module 1270 based on the application of multiple pseudo channels in the memory. More specifically, memory controller 1220 can schedule commands based on knowing the timing associated with the pseudo channel configuration. Additionally, the memory controller will know when to place write data on the data bus and when to receive read data on the data bus.

Memory controller 1220 represents one or more memory controller circuits or devices for system 1200. Memory controller 1220 represents control logic that generates memory access commands in response to the execution of operations by processor 1210. Memory controller 1220 accesses one or more memory devices 1240. Memory devices 1240 can be DRAM devices in accordance with any referred to above. In one example, memory devices 1240 are organized and managed as different channels, where each channel couples to buses and signal lines that couple to multiple memory devices in parallel. Each channel is independently operable. Thus, each channel is independently accessed and controlled, and the timing, data transfer, command and address exchanges, and other operations are separate for each channel. Coupling can refer to an electrical coupling, communicative coupling, physical coupling, or a combination of these. Physical coupling can include direct contact. Electrical coupling includes an interface or interconnection that allows electrical flow between components, or allows signaling between components, or both. Communicative coupling includes connections, including wired or wireless, that enable components to exchange data.

In one example, settings for each channel are controlled by separate mode registers or other register settings. In one example, each memory controller 1220 manages a separate memory channel, although system 1200 can be configured to have multiple channels managed by a single controller, or to have multiple controllers on a single channel. In one example, memory controller 1220 is part of host processor 1210, such as logic implemented on the same die or implemented in the same package space as the processor.

Processor 1210 represents a processing unit of a computing platform that may execute an operating system (OS) and applications, which can collectively be referred to as the host or the user of the memory. The OS and applications execute operations that result in memory accesses. Processor 1210 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or hard disk controller. Such devices can be integrated with the processor in some systems or attached to the processer via a bus (e.g., PCI express), or a combination. System 1200 can be implemented as an SOC (system on a chip), or be implemented with standalone components.

Reference to memory devices can apply to different memory types. Memory devices often refers to volatile memory technologies. Volatile memory is memory whose state (and therefore the data stored on it) is indeterminate if power is interrupted to the device. Nonvolatile memory refers to memory whose state is determinate even if power is interrupted to the device. Dynamic volatile memory requires refreshing the data stored in the device to maintain state. One example of dynamic volatile memory includes DRAM (dynamic random-access memory), or some variant such as synchronous DRAM (SDRAM). A memory subsystem as described herein may be compatible with a number of memory technologies, such as DDR4 (double data rate version 4, JESD79-4, originally published in September 2012 by JEDEC (Joint Electron Device Engineering Council, now the JEDEC Solid State Technology Association), LPDDR4 (low power DDR version 4, JESD209-4, originally published by JEDEC in August 2014), WIO2 (Wide I/O 2 (WideIO2), JESD229-2, originally published by JEDEC in August 2014), HBM (high bandwidth memory DRAM, JESD235A, originally published by JEDEC in November 2015), DDR5 (DDR version 5, JESD79-5, originally published by JEDEC in July 2020), LPDDR5 (LPDDR version 5, JESD209-5, originally published by JEDEC in February 2019), HBM2 ((HBM version 2), currently in discussion by JEDEC), or others or combinations of memory technologies, and technologies based on derivatives or extensions of such specifications.

Memory controller 1220 includes I/O interface logic 1222 to couple to a memory bus, such as a memory channel as referred to above. I/O interface logic 1222 (as well as I/O interface logic 1242 of memory device 1240) can include pins, pads, connectors, signal lines, traces, or wires, or other hardware to connect the devices, or a combination of these. I/O interface logic 1222 can include a hardware interface. As illustrated, I/O interface logic 1222 includes at least drivers/transceivers for signal lines. Commonly, wires within an integrated circuit interface couple with a pad, pin, or connector to interface signal lines or traces or other wires between devices. I/O interface logic 1222 can include drivers, receivers, transceivers, or termination, or other circuitry or combinations of circuitry to exchange signals on the signal lines between the devices. The exchange of signals includes at least one of transmit or receive. While shown as coupling I/O 1222 from memory controller 1220 to I/O 1242 of memory device 1240, it will be understood that in an implementation of system 1200 where groups of memory devices 1240 are accessed in parallel, multiple memory devices can include I/O interfaces to the same interface of memory controller 1220. In an implementation of system 1200 including one or more memory modules 1270, I/O 1242 can include interface hardware of the memory module in addition to interface hardware on the memory device itself. Other memory controllers 1220 will include separate interfaces to other memory devices 1240.

The bus between memory controller 1220 and memory devices 1240 can be implemented as multiple signal lines coupling memory controller 1220 to memory devices 1240. The bus may typically include at least clock (CLK) 1232, command/address (CMD) 1234, and write data (DQ) and read data (DQ) 1236, and zero or more other signal lines 1238. In one example, a bus or connection between memory controller 1220 and memory can be referred to as a memory bus. In one example, the memory bus is a multi-drop bus. The signal lines for CMD can be referred to as a “C/A bus” (or ADD/CMD bus, or some other designation indicating the transfer of commands (C or CMD) and address (A or ADD) information) and the signal lines for write and read DQ can be referred to as a “data bus.” In one example, independent channels have different clock signals, C/A buses, data buses, and other signal lines. Thus, system 1200 can be considered to have multiple “buses,” in the sense that an independent interface path can be considered a separate bus. It will be understood that in addition to the lines explicitly shown, a bus can include at least one of strobe signaling lines, alert lines, auxiliary lines, or other signal lines, or a combination. It will also be understood that serial bus technologies can be used for the connection between memory controller 1220 and memory devices 1240. An example of a serial bus technology is 8B10B encoding and transmission of high-speed data with embedded clock over a single differential pair of signals in each direction. In one example, CMD 1234 represents signal lines shared in parallel with multiple memory devices. In one example, multiple memory devices share encoding command signal lines of CMD 1234, and each has a separate chip select (CS_n) signal line to select individual memory devices.

It will be understood that in the example of system 1200, the bus between memory controller 1220 and memory devices 1240 includes a subsidiary command bus CMD 1234 and a subsidiary bus to carry the write and read data, DQ 1236. In one example, the data bus can include bidirectional lines for read data and for write/command data. In another example, the subsidiary bus DQ 1236 can include unidirectional write signal lines for write and data from the host to memory, and can include unidirectional lines for read data from the memory to the host. In accordance with the chosen memory technology and system design, other signals 1238 may accompany a bus or sub bus, such as strobe lines DQS. Based on design of system 1200, or implementation if a design supports multiple implementations, the data bus can have more or less bandwidth per memory device 1240. For example, the data bus can support memory devices that have either a ×4 interface, a ×8 interface, a ×16 interface, or other interface. The convention “×W,” where W is an integer that refers to an interface size or width of the interface of memory device 1240, which represents a number of signal lines to exchange data with memory controller 1220. The interface size of the memory devices is a controlling factor on how many memory devices can be used concurrently per channel in system 1200 or coupled in parallel to the same signal lines. In one example, high bandwidth memory devices, wide interface devices, or stacked memory configurations, or combinations, can enable wider interfaces, such as a ×128 interface, a ×256 interface, a ×512 interface, a ×1024 interface, or other data bus interface width.

In one example, memory devices 1240 and memory controller 1220 exchange data over the data bus in a burst, or a sequence of consecutive data transfers. The burst corresponds to a number of transfer cycles, which is related to a bus frequency. In one example, the transfer cycle can be a whole clock cycle for transfers occurring on a same clock or strobe signal edge (e.g., on the rising edge). In one example, every clock cycle, referring to a cycle of the system clock, is separated into multiple unit intervals (UIs), where each UI is a transfer cycle. For example, double data rate transfers trigger on both edges of the clock signal (e.g., rising and falling). A burst can last for a configured number of UIs, which can be a configuration stored in a register, or triggered on the fly. For example, a sequence of eight consecutive transfer periods can be considered a burst length eight (BL8), and each memory device 1240 can transfer data on each UI. Thus, a ×8 memory device operating on BL8 can transfer 64 bits of data (8 data signal lines times 8 data bits transferred per line over the burst). It will be understood that this simple example is merely an illustration and is not limiting.

Memory devices 1240 represent memory resources for system 1200. In one example, each memory device 1240 is a separate memory die. In one example, each memory device 1240 can interface with multiple (e.g., 2) channels per device or die. Each memory device 1240 includes I/O interface logic 1242, which has a bandwidth determined by the implementation of the device (e.g., ×16 or ×8 or some other interface bandwidth). I/O interface logic 1242 enables the memory devices to interface with memory controller 1220. I/O interface logic 1242 can include a hardware interface, and can be in accordance with I/O 1222 of memory controller, but at the memory device end. In one example, multiple memory devices 1240 are connected in parallel to the same command and data buses. In another example, multiple memory devices 1240 are connected in parallel to the same command bus, and are connected to different data buses. For example, system 1200 can be configured with multiple memory devices 1240 coupled in parallel, with each memory device responding to a command, and accessing memory resources 1260 internal to each. For a Write operation, an individual memory device 1240 can write a portion of the overall data word, and for a Read operation, an individual memory device 1240 can fetch a portion of the overall data word. The remaining bits of the word will be provided or received by other memory devices in parallel.

In one example, memory devices 1240 are disposed directly on a motherboard or host system platform (e.g., a PCB (printed circuit board) on which processor 1210 is disposed) of a computing device. In one example, memory devices 1240 can be organized into memory modules 1270. In one example, memory modules 1270 represent dual inline memory modules (DIMMs). In one example, memory modules 1270 represent other organization of multiple memory devices to share at least a portion of access or control circuitry, which can be a separate circuit, a separate device, or a separate board from the host system platform. Memory modules 1270 can include multiple memory devices 1240, and the memory modules can include support for multiple separate channels to the included memory devices disposed on them. In another example, memory devices 1240 may be incorporated into the same package as memory controller 1220, such as by techniques such as multi-chip-module (MCM), package-on-package, through-silicon via (TSV), or other techniques or combinations. Similarly, in one example, multiple memory devices 1240 may be incorporated into memory modules 1270, which themselves may be incorporated into the same package as memory controller 1220. It will be appreciated that for these and other implementations, memory controller 1220 may be part of host processor 1210.

Memory devices 1240 each include one or more memory arrays 1260. Memory array 1260 represents addressable memory locations or storage locations for data. Typically, memory array 1260 is managed as rows of data, accessed via wordline (rows) and bitline (individual bits within a row) control. Memory array 1260 can be organized as separate channels, ranks, and banks of memory. Channels may refer to independent control paths to storage locations within memory devices 1240. Ranks may refer to common locations across multiple memory devices (e.g., same row addresses within different devices) in parallel. Banks may refer to sub-arrays of memory locations within a memory device 1240. In one example, banks of memory are divided into sub-banks with at least a portion of shared circuitry (e.g., drivers, signal lines, control logic) for the sub-banks, allowing separate addressing and access. It will be understood that channels, ranks, banks, sub-banks, bank groups, or other organizations of the memory locations, and combinations of the organizations, can overlap in their application to physical resources. For example, the same physical memory locations can be accessed over a specific channel as a specific bank, which can also belong to a rank. Thus, the organization of memory resources will be understood in an inclusive, rather than exclusive, manner.

In one example, memory devices 1240 include one or more registers 1244. Register 1244 represents one or more storage devices or storage locations that provide configuration or settings for the operation of the memory device. In one example, register 1244 can provide a storage location for memory device 1240 to store data for access by memory controller 1220 as part of a control or management operation. In one example, register 1244 includes one or more Mode Registers. In one example, register 1244 includes one or more multipurpose registers. The configuration of locations within register 1244 can configure memory device 1240 to operate in different “modes,” where command information can trigger different operations within memory device 1240 based on the mode. Additionally or in the alternative, different modes can also trigger different operation from address information or other signal lines depending on the mode. Settings of register 1244 can indicate configuration for I/O settings (e.g., timing, termination or ODT (on-die termination) 1246, driver configuration, or other I/O settings).

In one example, memory device 1240 includes ODT 1246 as part of the interface hardware associated with I/O 1242. ODT 1246 can be configured as mentioned above, and provide settings for impedance to be applied to the interface to specified signal lines. In one example, ODT 1246 is applied to DQ signal lines. In one example, ODT 1246 is applied to command signal lines. In one example, ODT 1246 is applied to address signal lines. In one example, ODT 1246 can be applied to any combination of the preceding. The ODT settings can be changed based on whether a memory device is a selected target of an access operation or a non-target device. ODT 1246 settings can affect the timing and reflections of signaling on the terminated lines. Careful control over ODT 1246 can enable higher-speed operation with improved matching of applied impedance and loading. ODT 1246 can be applied to specific signal lines of I/O interface 1242, 1222 (for example, ODT for DQ lines or ODT for CA lines), and is not necessarily applied to all signal lines.

Memory device 1240 includes controller 1250, which represents control logic within the memory device to control internal operations within the memory device. For example, controller 1250 decodes commands sent by memory controller 1220 and generates internal operations to execute or satisfy the commands. Controller 1250 can be referred to as an internal controller, and is separate from memory controller 1220 of the host. Controller 1250 can determine what mode is selected based on register 1244, and configure the internal execution of operations for access to memory resources 1260 or other operations based on the selected mode. Controller 1250 generates control signals to control the routing of bits within memory device 1240 to provide a proper interface for the selected mode and direct a command to the proper memory locations or addresses. Controller 1250 includes command logic 1252, which can decode command encoding received on command and address signal lines. Thus, command logic 1252 can be or include a command decoder. With command logic 1252, memory device can identify commands and generate internal operations to execute requested commands.

Referring again to memory controller 1220, memory controller 1220 includes command (CMD) logic 1224, which represents logic or circuitry to generate commands to send to memory devices 1240. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In response to scheduling of transactions for memory device 1240, memory controller 1220 can issue commands via I/O 1222 to cause memory device 1240 to execute the commands. In one example, controller 1250 of memory device 1240 receives and decodes command and address information received via I/O 1242 from memory controller 1220. Based on the received command and address information, controller 1250 can control the timing of operations of the logic and circuitry within memory device 1240 to execute the commands. Controller 1250 is responsible for compliance with standards or specifications within memory device 1240, such as timing and signaling requirements. Memory controller 1220 can implement compliance with standards or specifications by access scheduling and control.

Memory controller 1220 includes scheduler 1230, which represents logic or circuitry to generate and order transactions to send to memory device 1240. From one perspective, the primary function of memory controller 1220 could be said to schedule memory access and other transactions to memory device 1240. Such scheduling can include generating the transactions themselves to implement the requests for data by processor 1210 and to maintain integrity of the data (e.g., such as with commands related to refresh). Transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands or a combination.

Memory controller 1220 typically includes logic such as scheduler 1230 to allow selection and ordering of transactions to improve performance of system 1200. Thus, memory controller 1220 can select which of the outstanding transactions should be sent to memory device 1240 in which order, which is typically achieved with logic much more complex that a simple first-in first-out algorithm. Memory controller 1220 manages the transmission of the transactions to memory device 1240, and manages the timing associated with the transaction. In one example, transactions have deterministic timing, which can be managed by memory controller 1220 and used in determining how to schedule the transactions with scheduler 1230.

In one example, memory controller 1220 includes refresh (REF) logic 1226. Refresh logic 1226 can be used for memory resources that are volatile and need to be refreshed to retain a deterministic state. In one example, refresh logic 1226 indicates a location for refresh, and a type of refresh to perform. Refresh logic 1226 can trigger self-refresh within memory device 1240, or execute external refreshes which can be referred to as auto refresh commands) by sending refresh commands, or a combination. In one example, controller 1250 within memory device 1240 includes refresh logic 1254 to apply refresh within memory device 1240. In one example, refresh logic 1254 generates internal operations to perform refresh in accordance with an external refresh received from memory controller 1220. Refresh logic 1254 can determine if a refresh is directed to memory device 1240, and what memory resources 1260 to refresh in response to the command.

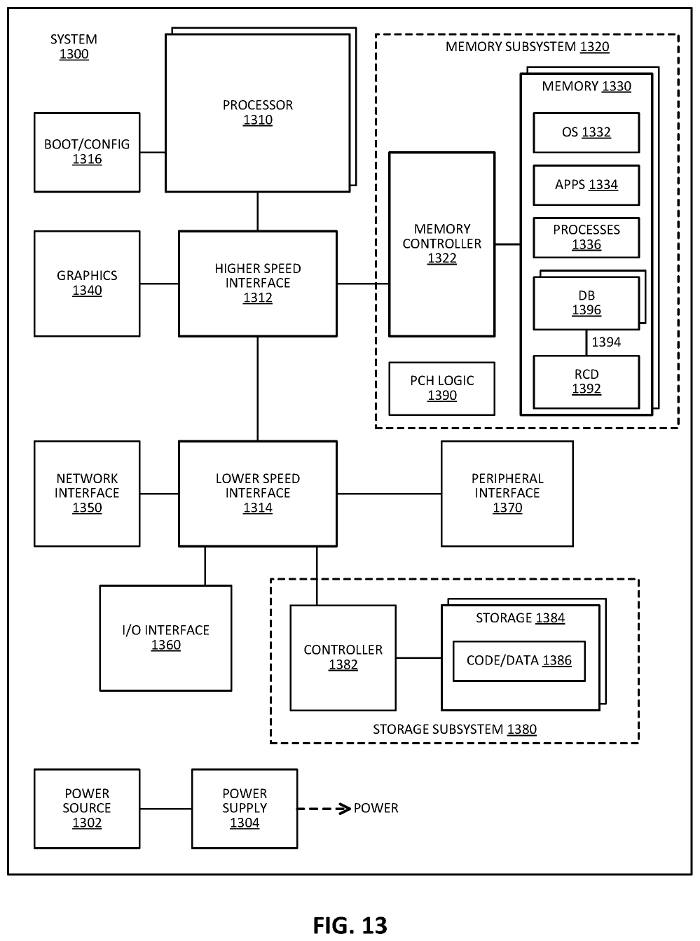

FIG. 13 is a block diagram of an example of a computing system in which pseudo channels can be implemented. System 1300 represents a computing device in accordance with any example herein, and can be a laptop computer, a desktop computer, a tablet computer, a server, a gaming or entertainment control system, embedded computing device, or other electronic device.

System 1300 represents a system in accordance with any example herein of an MRDIMM. In one example, memory module 1330 represents a memory module, including RCD 1392, which represents a registering clock driver in accordance with any example herein. In one example, memory 1330 includes DBs 1396, which represent data buffers in accordance with any example herein. DBs 1396 provide a connection to a data bus with memory controller 1322 to buffer data transfer between memory 1330 and memory controller 1322. RCD 1392 can control the operation of DBs 1396 through BCOM 1394. System 1300 includes PCH logic 1390 to control the operation of pseudo channels in accordance with any example herein. PCH logic 1390 can include logic in memory controller 1322, RCD 1392, and DBs 1396.

System 1300 includes processor 1310 can include any type of microprocessor, central processing unit (CPU), graphics processing unit (GPU), processing core, or other processing hardware, or a combination, to provide processing or execution of instructions for system 1300. Processor 1310 can be a host processor device. Processor 1310 controls the overall operation of system 1300, and can be or include, one or more programmable general-purpose or special-purpose microprocessors, digital signal processors (DSPs), programmable controllers, application specific integrated circuits (ASICs), programmable logic devices (PLDs), or a combination of such devices.

System 1300 includes boot/config 1316, which represents storage to store boot code (e.g., basic input/output system (BIOS)), configuration settings, security hardware (e.g., trusted platform module (TPM)), or other system level hardware that operates outside of a host OS. Boot/config 1316 can include a nonvolatile storage device, such as read-only memory (ROM), flash memory, or other memory devices.

In one example, system 1300 includes interface 1312 coupled to processor 1310, which can represent a higher speed interface or a high throughput interface for system components that need higher bandwidth connections, such as memory subsystem 1320 or graphics interface components 1340. Interface 1312 represents an interface circuit, which can be a standalone component or integrated onto a processor die. Interface 1312 can be integrated as a circuit onto the processor die or integrated as a component on a system on a chip. Where present, graphics interface 1340 interfaces to graphics components for providing a visual display to a user of system 1300. Graphics interface 1340 can be a standalone component or integrated onto the processor die or system on a chip. In one example, graphics interface 1340 can drive a high definition (HD) display or ultra high definition (UHD) display that provides an output to a user. In one example, the display can include a touchscreen display. In one example, graphics interface 1340 generates a display based on data stored in memory 1330 or based on operations executed by processor 1310 or both.

Memory subsystem 1320 represents the main memory of system 1300, and provides storage for code to be executed by processor 1310, or data values to be used in executing a routine. Memory subsystem 1320 can include one or more varieties of random-access memory (RAM) such as DRAM, 3DXP (three-dimensional crosspoint), or other memory devices, or a combination of such devices. Memory 1330 stores and hosts, among other things, operating system (OS) 1332 to provide a software platform for execution of instructions in system 1300. Additionally, applications 1334 can execute on the software platform of OS 1332 from memory 1330. Applications 1334 represent programs that have their own operational logic to perform execution of one or more functions. Processes 1336 represent agents or routines that provide auxiliary functions to OS 1332 or one or more applications 1334 or a combination. OS 1332, applications 1334, and processes 1336 provide software logic to provide functions for system 1300. In one example, memory subsystem 1320 includes memory controller 1322, which is a memory controller to generate and issue commands to memory 1330. It will be understood that memory controller 1322 could be a physical part of processor 1310 or a physical part of interface 1312. For example, memory controller 1322 can be an integrated memory controller, integrated onto a circuit with processor 1310, such as integrated onto the processor die or a system on a chip.

While not specifically illustrated, it will be understood that system 1300 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or other bus, or a combination.

In one example, system 1300 includes interface 1314, which can be coupled to interface 1312. Interface 1314 can be a lower speed interface than interface 1312. In one example, interface 1314 represents an interface circuit, which can include standalone components and integrated circuitry. In one example, multiple user interface components or peripheral components, or both, couple to interface 1314. Network interface 1350 provides system 1300 the ability to communicate with remote devices (e.g., servers or other computing devices) over one or more networks. Network interface 1350 can include an Ethernet adapter, wireless interconnection components, cellular network interconnection components, USB (universal serial bus), or other wired or wireless standards-based or proprietary interfaces. Network interface 1350 can exchange data with a remote device, which can include sending data stored in memory or receiving data to be stored in memory.

In one example, system 1300 includes one or more input/output (I/O) interface(s) 1360. I/O interface 1360 can include one or more interface components through which a user interacts with system 1300 (e.g., audio, alphanumeric, tactile/touch, or other interfacing). Peripheral interface 1370 can include any hardware interface not specifically mentioned above. Peripherals refer generally to devices that connect dependently to system 1300. A dependent connection is one where system 1300 provides the software platform or hardware platform or both on which operation executes, and with which a user interacts.

In one example, system 1300 includes storage subsystem 1380 to store data in a nonvolatile manner. In one example, in certain system implementations, at least certain components of storage 1380 can overlap with components of memory subsystem 1320. Storage subsystem 1380 includes storage device(s) 1384, which can be or include any conventional medium for storing large amounts of data in a nonvolatile manner, such as one or more magnetic, solid state, NAND, 3DXP, or optical based disks, or a combination. Storage 1384 holds code or instructions and data 1386 in a persistent state (i.e., the value is retained despite interruption of power to system 1300). Storage 1384 can be generically considered to be a “memory,” although memory 1330 is typically the executing or operating memory to provide instructions to processor 1310. Whereas storage 1384 is nonvolatile, memory 1330 can include volatile memory (i.e., the value or state of the data is indeterminate if power is interrupted to system 1300). In one example, storage subsystem 1380 includes controller 1382 to interface with storage 1384. In one example controller 1382 is a physical part of interface 1314 or processor 1310, or can include circuits or logic in both processor 1310 and interface 1314.

Power source 1302 provides power to the components of system 1300. More specifically, power source 1302 typically interfaces to one or multiple power supplies 1304 in system 1300 to provide power to the components of system 1300. In one example, power supply 1304 includes an AC to DC (alternating current to direct current) adapter to plug into a wall outlet. Such AC power can be renewable energy (e.g., solar power) power source 1302. In one example, power source 1302 includes a DC power source, such as an external AC to DC converter. In one example, power source 1302 or power supply 1304 includes wireless charging hardware to charge via proximity to a charging field. In one example, power source 1302 can include an internal battery or fuel cell source.

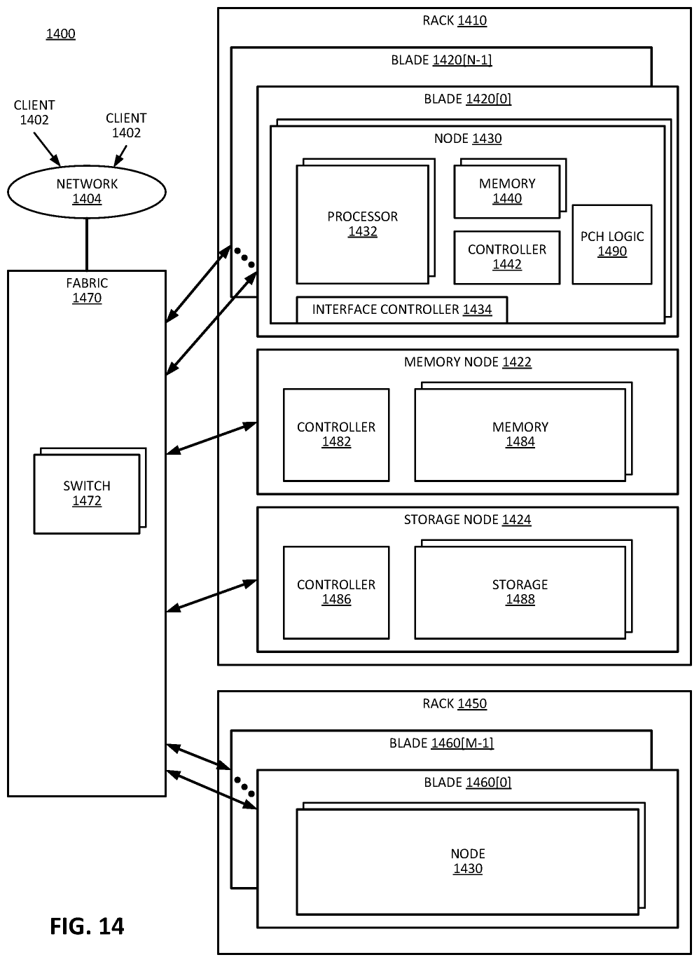

FIG. 14 is a block diagram of an example of a multi-node network in which pseudo channels can be implemented. System 1400 represents a network of nodes. In one example, system 1400 represents a data center. In one example, system 1400 represents a server farm. In one example, system 1400 represents a data cloud or a processing cloud.

System 1400 includes nodes 1430, which includes an MRDIMM in accordance with any example herein. In one example, memory node 1422 can include an MRDIMM in accordance with any example herein. In one example, node 1430 (or memory node 1422, or both) includes PCH logic 1490 to control the operation of pseudo channels in accordance with any example herein. PCH logic 1490 can include logic in controller 1442 and memory 1440.

One or more clients 1402 make requests over network 1404 to system 1400. Network 1404 represents one or more local networks, or wide area networks, or a combination. Clients 1402 can be human or machine clients, which generate requests for the execution of operations by system 1400. System 1400 executes applications or data computation tasks requested by clients 1402.

In one example, system 1400 includes one or more racks, which represent structural and interconnect resources to house and interconnect multiple computation nodes. In one example, rack 1410 includes multiple nodes 1430. In one example, rack 1410 hosts multiple blade components, blade 1420[0], . . . , blade 1420[N−1], collectively blades 1420. Hosting refers to providing power, structural or mechanical support, and interconnection. Blades 1420 can refer to computing resources on printed circuit boards (PCBs), where a PCB houses the hardware components for one or more nodes 1430. In one example, blades 1420 do not include a chassis or housing or other “box” other than that provided by rack 1410. In one example, blades 1420 include housing with exposed connector to connect into rack 1410. In one example, system 1400 does not include rack 1410, and each blade 1420 includes a chassis or housing that can stack or otherwise reside in close proximity to other blades and allow interconnection of nodes 1430.

System 1400 includes fabric 1470, which represents one or more interconnectors for nodes 1430. In one example, fabric 1470 includes multiple switches 1472 or routers or other hardware to route signals among nodes 1430. Additionally, fabric 1470 can couple system 1400 to network 1404 for access by clients 1402. In addition to routing equipment, fabric 1470 can be considered to include the cables or ports or other hardware equipment to couple nodes 1430 together. In one example, fabric 1470 has one or more associated protocols to manage the routing of signals through system 1400. In one example, the protocol or protocols is at least partly dependent on the hardware equipment used in system 1400.

As illustrated, rack 1410 includes N blades 1420. In one example, in addition to rack 1410, system 1400 includes rack 1450. As illustrated, rack 1450 includes M blade components, blade 1460[0], . . . , blade 1460[M−1], collectively blades 1460. M is not necessarily the same as N; thus, it will be understood that various different hardware equipment components could be used, and coupled together into system 1400 over fabric 1470. Blades 1460 can be the same or similar to blades 1420. Nodes 1430 can be any type of node and are not necessarily all the same type of node. System 1400 is not limited to being homogenous, nor is it limited to not being homogenous.

The nodes in system 1400 can include compute nodes, memory nodes, storage nodes, accelerator nodes, or other nodes. Rack 1410 is represented with memory node 1422 and storage node 1424, which represent shared system memory resources, and shared persistent storage, respectively. One or more nodes of rack 1450 can be a memory node or a storage node.

Nodes 1430 represent examples of compute nodes. For simplicity, only the compute node in blade 1420[0] is illustrated in detail. However, other nodes in system 1400 can be the same or similar. At least some nodes 1430 are computation nodes, with processor (proc) 1432 and memory 1440. A computation node refers to a node with processing resources (e.g., one or more processors) that executes an operating system and can receive and process one or more tasks. In one example, at least some nodes 1430 are server nodes with a server as processing resources represented by processor 1432 and memory 1440.

Memory node 1422 represents an example of a memory node, with system memory external to the compute nodes. Memory nodes can include controller 1482, which represents a processor on the node to manage access to the memory. The memory nodes include memory 1484 as memory resources to be shared among multiple compute nodes.

Storage node 1424 represents an example of a storage server, which refers to a node with more storage resources than a computation node, and rather than having processors for the execution of tasks, a storage server includes processing resources to manage access to the storage nodes within the storage server. Storage nodes can include controller 1486 to manage access to the storage 1488 of the storage node.

In one example, node 1430 includes interface controller 1434, which represents logic to control access by node 1430 to fabric 1470. The logic can include hardware resources to interconnect to the physical interconnection hardware. The logic can include software or firmware logic to manage the interconnection. In one example, interface controller 1434 is or includes a host fabric interface, which can be a fabric interface in accordance with any example described herein. The interface controllers for memory node 1422 and storage node 1424 are not explicitly shown.

Processor 1432 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory 1440 can be or include memory devices represented by memory 1440 and a memory controller represented by controller 1442.

In general with respect to the descriptions herein, in one aspect an apparatus includes: a command/address (CA) bus; multiple dynamic random access (DRAM) devices coupled to the CA bus; and a registering clock driver (RCD) to time division multiplex separate first commands for a first group of the DRAM devices from second commands for a second group of the DRAM devices on the CA bus, wherein the RCD is to issue two column address strobe (CAS) commands with a single read command to exchange a double amount of data per DRAM device per read command.

In one example of the apparatus, the RCD is to drive two CA buses per channel, to provide four pseudo channels per channel. In accordance with any preceding example of the apparatus, in one example, the apparatus includes: a printed circuit board (PCB) having DRAM devices on a front side of the PCB and on a back side of the PCB, with a pseudo channel having data bus interfaces of DRAM devices on the front side and on the back side multiplexed to a same data buffer, with extra chip select signal lines between the RCD and the multiple DRAM devices as compared to a number of chip select signal lines between a host memory controller and the RCD. In accordance with any preceding example of the apparatus, in one example, the RCD is to receive a single CAS command with the single read command, and issue the two CAS commands to the DRAM devices. In accordance with any preceding example of the apparatus, in one example, the RCD is to receive a two CAS commands with the single read command from the memory controller, and issue the two CAS commands to the DRAM devices. In accordance with any preceding example of the apparatus, in one example, the apparatus includes: a data bus to couple to a host memory controller; and multiple data buffers coupled between the multiple DRAM devices and the host memory controller on the data bus. In accordance with any preceding example of the apparatus, in one example, the apparatus includes: a data mask signal per 8 signal lines of the data bus, wherein the multiple DRAM devices are to provide error correction coding (ECC) information to the host memory controller via the data mask signal. In accordance with any preceding example of the apparatus, in one example, the ECC information comprises internal ECC bits generated by on-die ECC on the multiple DRAM devices. In accordance with any preceding example of the apparatus, in one example, each DRAM device has a ×8 data bus interface to exchange 8 data bits per unit interval with the data bus. In accordance with any preceding example of the apparatus, in one example, each data buffer multiplexes data from DRAM devices of different pseudo channels. In accordance with any preceding example of the apparatus, in one example, each data buffer multiplexes data from DRAM devices of a single pseudo channel. In accordance with any preceding example of the apparatus, in one example, each DRAM device has a ×16 data bus interface to exchange 16 data bits per unit interval with the data bus. In accordance with any preceding example of the apparatus, in one example, each data buffer multiplexes data from DRAM devices of different pseudo channels. In accordance with any preceding example of the apparatus, in one example, each data buffer multiplexes data from a single DRAM device of a single pseudo channel. In accordance with any preceding example of the apparatus, in one example, the apparatus includes a dedicated data buffer per DRAM device.

In general with respect to the descriptions herein, in one aspect, a system includes: a memory controller; and a memory module coupled to the memory controller, the memory module including: a command/address (CA) bus; multiple dynamic random access (DRAM) devices coupled to the CA bus; and a registering clock driver (RCD) to time division multiplex separate first commands for a first group of the DRAM devices from second commands for a second group of the DRAM devices on the CA bus, wherein the RCD is to issue two column address strobe (CAS) commands with a single read command to exchange a double amount of data per DRAM device per read command.

In one example of the system, the RCD is to drive two CA buses per channel, to provide four pseudo channels per channel. In accordance with any preceding example of the system, in one example, the RCD is to receive a single CAS command with the single read command, and issue the two CAS commands to the DRAM devices. In accordance with any preceding example of the system, in one example, the RCD is to receive a two CAS commands with the single read command from the memory controller, and issue the two CAS commands to the DRAM devices. In accordance with any preceding example of the system, in one example, the memory module comprises a printed circuit board (PCB) having DRAM devices on a front side of the PCB and on a back side of the PCB, with a pseudo channel having data bus interfaces of DRAM devices on the front side and on the back side multiplexed to a same data buffer, with extra chip select signal lines between the RCD and the multiple DRAM devices as compared to a number of chip select signal lines between the memory controller and the RCD. In accordance with any preceding example of the system, in one example, the memory module includes: multiple data buffers coupled between the multiple DRAM devices and the memory controller on a data bus. In accordance with any preceding example of the system, in one example, the system includes: a data mask signal per 8 signal lines of the data bus, wherein the multiple DRAM devices are to provide error correction coding (ECC) information to the memory controller via the data mask signal. In accordance with any preceding example of the system, in one example, the ECC information comprises internal ECC bits generated by on-die ECC on the multiple DRAM devices. In accordance with any preceding example of the system, in one example, each DRAM device has a ×8 data bus interface to exchange 8 data bits per unit interval with the data bus. In accordance with any preceding example of the system, in one example, each data buffer multiplexes data from DRAM devices of different pseudo channels. In accordance with any preceding example of the system, in one example, each data buffer multiplexes data from DRAM devices of a single pseudo channel. In accordance with any preceding example of the system, in one example, each DRAM device has a ×16 data bus interface to exchange 16 data bits per unit interval with the data bus. In accordance with any preceding example of the system, in one example, each data buffer multiplexes data from DRAM devices of different pseudo channels. In accordance with any preceding example of the system, in one example, each data buffer multiplexes data from DRAM devices of a single pseudo channel. In accordance with any preceding example of the system, in one example, the memory module includes a dedicated data buffer per DRAM device. In accordance with any preceding example of the system, in one example, the system includes one or more of: a host processor coupled to the memory module; a display communicatively coupled to a host processor; a network interface communicatively coupled to a host processor; or a battery to power the system.

In general with respect to the descriptions herein, in one aspect a memory controller includes: an interface to couple to a data bus to exchange data with multiple dynamic random access (DRAM) devices coupled to the CA bus; an interface to couple to a command/address (CA) bus to send commands to a registering clock driver (RCD), wherein in response to the commands, the RCD is to time division multiplex separate first commands for a first group of the DRAM devices from second commands for a second group of the DRAM devices on the CA bus, wherein the RCD is to issue two column address strobe (CAS) commands with a single read command to exchange a double amount of data per DRAM device per read command; and a scheduler to manage scheduling for exchange of data with the multiple DRAM devices based on issuance of the two CAS commands.

In one example of the memory controller, the RCD is to drive two CA buses per channel, to provide four pseudo channels per channel. In accordance with any preceding example of the memory controller, the scheduler is to schedule data exchange based on the multiple DRAM devices being on a front side of the memory module and on a back side of the memory module, with a pseudo channel having data bus interfaces of DRAM devices on the front side and on the back side multiplexed to a same data buffer, with extra chip select signal lines between the RCD and the multiple DRAM devices as compared to a number of chip select signal lines between the memory controller and the RCD. In accordance with any preceding example of the memory controller, the memory controller is to send a single CAS command with the single read command, and the RCD is to issue the two CAS commands to the DRAM devices. In accordance with any preceding example of the memory controller, the memory controller is to send two CAS commands with the single read command, and the RCD is to issue the two CAS commands to the DRAM devices. In accordance with any preceding example of the memory controller, wherein a memory module having the RCD includes multiple data buffers coupled between the multiple DRAM devices and the memory controller on the data bus. In accordance with any preceding example of the memory controller, the data bus includes a data mask signal per 8 signal lines of the data bus, wherein the multiple DRAM devices are to provide error correction coding (ECC) information to the memory controller via the data mask signal. In accordance with any preceding example of the memory controller, the ECC information comprises internal ECC bits generated by on-die ECC on the multiple DRAM devices. In accordance with any preceding example of the memory controller, each DRAM device has a ×8 data bus interface to exchange 8 data bits per unit interval with the data bus. In accordance with any preceding example of the memory controller, each data buffer multiplexes data from DRAM devices of different pseudo channels. In accordance with any preceding example of the memory controller, each data buffer multiplexes data from DRAM devices of a single pseudo channel. In accordance with any preceding example of the memory controller, each DRAM device has a ×16 data bus interface to exchange 16 data bits per unit interval with the data bus. In accordance with any preceding example of the memory controller, each data buffer multiplexes data from DRAM devices of different pseudo channels. In accordance with any preceding example of the memory controller, each data buffer multiplexes data from a single DRAM device of a single pseudo channel.

In general with respect to the descriptions herein, in one aspect, a multiplexed ranks dual inline memory module (MRDIMM) includes: a command/address (CA) bus; a data bus to couple to a host memory controller; multiple dynamic random access (DRAM) devices coupled to the CA bus; multiple data buffers coupled between the multiple DRAM devices and the memory controller on the data bus; and a registering clock driver (RCD) to time division multiplex separate first commands for a first group of the DRAM devices from second commands for a second group of the DRAM devices on the CA bus, wherein the RCD is to issue two column address strobe (CAS) commands with a single read command to exchange a double amount of data per DRAM device per read command.

In one example of the MRDIMM, the RCD is to drive two CA buses per channel, to provide four pseudo channels per channel. In accordance with any preceding example of the MRDIMM, in one example, the RCD is to receive a single CAS command with the single read command, and issue the two CAS commands to the DRAM devices. In accordance with any preceding example of the MRDIMM, in one example, the RCD is to receive a two CAS commands with the single read command from the memory controller, and issue the two CAS commands to the DRAM devices. In accordance with any preceding example of the MRDIMM, in one example, the memory module comprises a printed circuit board (PCB) having DRAM devices on a front side of the PCB and on a back side of the PCB, with a pseudo channel having data bus interfaces of DRAM devices on the front side and on the back side multiplexed to a same data buffer, with extra chip select signal lines between the RCD and the multiple DRAM devices as compared to a number of chip select signal lines between the memory controller and the RCD. In accordance with any preceding example of the MRDIMM, in one example, the MRDIMM includes: a data mask signal per 8 signal lines of the data bus, wherein the multiple DRAM devices are to provide error correction coding (ECC) information to the memory controller via the data mask signal. In accordance with any preceding example of the MRDIMM, in one example, the ECC information comprises internal ECC bits generated by on-die ECC on the multiple DRAM devices. In accordance with any preceding example of the MRDIMM, in one example, each DRAM device has a ×8 data bus interface to exchange 8 data bits per unit interval with the data bus. In accordance with any preceding example of the MRDIMM, in one example, each data buffer multiplexes data from DRAM devices of different pseudo channels. In accordance with any preceding example of the MRDIMM, in one example, each data buffer multiplexes data from DRAM devices of a single pseudo channel. In accordance with any preceding example of the MRDIMM, in one example, each DRAM device has a ×16 data bus interface to exchange 16 data bits per unit interval with the data bus. In accordance with any preceding example of the MRDIMM, in one example, each data buffer multiplexes data from DRAM devices of different pseudo channels. In accordance with any preceding example of the MRDIMM, in one example, each data buffer multiplexes data from DRAM devices of a single pseudo channel. In accordance with any preceding example of the MRDIMM, in one example, the memory module includes a dedicated data buffer per DRAM device.

Flow diagrams as illustrated herein provide examples of sequences of various process actions. The flow diagrams can indicate operations to be executed by a software or firmware routine, as well as physical operations. A flow diagram can illustrate an example of the implementation of states of a finite state machine (FSM), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. An apparatus comprising:
a command/address (CA) bus;
multiple dynamic random access (DRAM) devices coupled to the CA bus; and
a registering clock driver (RCD) to time division multiplex separate first commands for a first group of the DRAM devices from second commands for a second group of the DRAM devices on the CA bus, wherein the RCD is to issue two column address strobe (CAS) commands with a single read command to exchange a double amount of data per DRAM device per read command.

2. The apparatus of claim 1, wherein the RCD is to drive two CA buses per channel, to provide four pseudo channels per channel.

3. The apparatus of claim 1, further comprising:
a printed circuit board (PCB) having DRAM devices on a front side of the PCB and on a back side of the PCB, with a pseudo channel having data bus interfaces of DRAM devices on the front side and on the back side multiplexed to a same data buffer, with extra chip select signal lines between the RCD and the multiple DRAM devices as compared to a number of chip select signal lines between a host memory controller and the RCD.

4. The apparatus of claim 1, wherein the RCD is to receive a single CAS command with the single read command, and issue the two CAS commands to the DRAM devices.

5. The apparatus of claim 1, further comprising:
a data bus to couple to a host memory controller; and
multiple data buffers coupled between the multiple DRAM devices and the host memory controller on the data bus.

6. The apparatus of claim 5, further comprising:
a data mask signal per 8 signal lines of the data bus, wherein the multiple DRAM devices are to provide error correction coding (ECC) information to the host memory controller via the data mask signal.

7. The apparatus of claim 6, wherein the ECC information comprises internal ECC bits generated by on-die ECC on the multiple DRAM devices.

8. The apparatus of claim 5, wherein each DRAM device has a ×8 data bus interface to exchange 8 data bits per unit interval with the data bus.

9. The apparatus of claim 8, wherein each data buffer multiplexes data from DRAM devices of different pseudo channels.

10. The apparatus of claim 8, wherein each data buffer multiplexes data from DRAM devices of a single pseudo channel.

11. The apparatus of claim 5, wherein each DRAM device has a ×16 data bus interface to exchange 16 data bits per unit interval with the data bus.

12. The apparatus of claim 11, wherein each data buffer multiplexes data from DRAM devices of different pseudo channels.

13. The apparatus of claim 11, wherein each data buffer multiplexes data from a single DRAM device of a single pseudo channel.

14. A system comprising:
a memory controller; and
a memory module coupled to the memory controller, the memory module including:
a command/address (CA) bus;
multiple dynamic random access (DRAM) devices coupled to the CA bus; and
a registering clock driver (RCD) to time division multiplex separate first commands for a first group of the DRAM devices from second commands for a second group of the DRAM devices on the CA bus, wherein the RCD is to issue two column address strobe (CAS) commands with a single read command to exchange a double amount of data per DRAM device per read command.

15. The system of claim 14, wherein the RCD is to receive a two CAS commands with the single read command from the memory controller, and issue the two CAS commands to the DRAM devices.

16. The system of claim 14, wherein the memory module comprises a printed circuit board (PCB) having DRAM devices on a front side of the PCB and on a back side of the PCB, with a pseudo channel having data bus interfaces of DRAM devices on the front side and on the back side multiplexed to a same data buffer, with extra chip select signal lines between the RCD and the multiple DRAM devices as compared to a number of chip select signal lines between the memory controller and the RCD.

17. The system of claim 14, the memory module further comprising:
multiple data buffers coupled between the multiple DRAM devices and the memory controller on a data bus.

18. The system of claim 17, further comprising:
a data mask signal per 8 signal lines of the data bus, wherein the multiple DRAM devices are to provide error correction coding (ECC) information to the memory controller via the data mask signal.

19. The system of claim 17, wherein each data buffer multiplexes data from DRAM devices of different pseudo channels.

20. The system of claim 17, wherein each data buffer multiplexes data from DRAM devices of a single pseudo channel.

21. The system of claim 14, including one or more of:
a host processor coupled to the memory module;
a display communicatively coupled to a host processor;
a network interface communicatively coupled to a host processor; or
a battery to power the system.
